(19) United States
(12) Patent Application Publication
(10) Pub. No.: US 2025/0299976 A1
(43) Pub. Date: Sep. 25, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Michinori IWAO, Kyoto-shi (JP); Yukifumi YOSHIDA, Kyoto-shi (JP); Tomohiro UEMURA, Kyoto-shi (JP); Shoyo MINAMI, Kyoto-shi (JP); Yusuke UEDA, Kyoto-shi (JP)

(21) Appl. No.: 19/069,137

(22) Filed: Mar. 3, 2025

(30) Foreign Application Priority Data
Mar. 19, 2024 (JP) 2024-043324

(51) Int. Cl. H01L 21/67

(52) U.S. Cl. CPC H01L 21/67023

(57) ABSTRACT

A circulation pipe is connected to a collection tank storing a mixed fluid containing water and an organic solvent, and includes: a first pipe connecting a downstream side of a second position and an upstream side of a first position; a second pipe connecting a downstream side of the first position and an upstream side of the second position; and a bypass pipe connecting the downstream side of the first position and the upstream side of the second position through a path different from that of the second pipe. The dewaterer is disposed in the first pipe or the bypass pipe, and the pump pressurizes the mixed fluid at a separation pressure higher than a circulation pressure and the heater heats the mixed fluid, in a state where the mixed fluid circulates through the first pipe and the bypass pipe.

### BACKGROUND

### Technical Field

The present disclosure relates to a substrate processing apparatus and a substrate processing method.

### Description of the Background Art

In substrate processing apparatuses used in manufacturing steps of semiconductor devices, etc., for example, a substrate is processed with a chemical liquid, and then rinsed out with a rinse liquid. In Japanese Patent Application Laid-Open No. 2017-41505, a substrate rinsed out with a rinse liquid (i.e., a substrate covered with a rinse liquid (typically, water)) is supplied with isopropyl alcohol (IPA) to replace the rinse liquid on the substrate with IPA. Then, the substrate is rotated at high speeds to blow off the IPA that adheres to the substrate, and is dried. When rotating the substrate at high speeds to blow off the adhering liquid, there is a risk that the surface tension of the adhering liquid may collapse a pattern. However, previous replacement of the water that adheres to the substrate with IPA with a surface tension lower than that of water suppresses the collapse of the pattern. Since IPA is bipolar, even when the surface of the substrate is hydrophobic, the substrate can evenly become wet. Thus, the dried substrate hardly has watermarks.

Japanese Patent Application Laid-Open No. 2017-41505 describes collecting IPA supplied to the substrate. Since IPA is supplied to the substrate covered with water, collected IPA is diluted with water (i.e., IPA is collected as a mixed solution of IPA and water). Thus, recycling the collected IPA requires separating water from the mixed solution.

In order to separate water from a mixed solution of water and an organic solvent such as IPA, for example, a separation membrane that allows water molecules to pass through and does not allow molecules of an organic solvent to pass through is probably used. In order to reduce the time required for the separation of water, it is necessary to enhance the separation efficiency using the separation membrane.

### SUMMARY

The present disclosure is directed to a substrate processing apparatus. The substrate processing apparatus according to one aspect of the disclosure includes: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a circulation pipe connected to the collection tank; a dewaterer disposed in the circulation pipe and including a separation membrane that allows the water to pass through and does not allow the organic solvent to pass through; a pump disposed in the circulation pipe; and a heater disposed in the circulation pipe, wherein a first position and a second position are defined in the circulation pipe, and the circulation pipe includes: a first pipe connecting a downstream side of the second position and an upstream side of the first position; a second pipe connecting a downstream side of the first position and an upstream side of the second position; and a bypass pipe connecting the downstream side of the first position and the upstream side of the second position through a path different from a path of the second pipe, the dewaterer is disposed in the first pipe or the bypass pipe, and the pump pressurizes the mixed fluid at a separation pressure higher than a circulation pressure necessary for circulation and the heater heats the mixed fluid to a predetermined heating temperature, in a state where the mixed fluid circulates through the first pipe and the bypass pipe.

The present disclosure is also directed to a substrate processing method. The substrate processing method according to one aspect of the disclosure includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; filling a circulation pipe connected to the collection tank with the mixed fluid stored in the collection tank; circulating the mixed fluid through a first pipe and a bypass pipe, among the first pipe, a second pipe, and the bypass pipe included in the circulation pipe; pressurizing the mixed fluid circulating through the first pipe and the bypass pipe, at a separation pressure higher than a circulation pressure necessary for circulation; heating the mixed fluid circulating through the first pipe and the bypass pipe, to a predetermined heating temperature; and causing the mixed fluid to flow into a dewaterer including a separation membrane that allows the water to pass through and does not allow the organic solvent to pass through, and separating the water from the mixed fluid, the mixed fluid circulating through the first pipe and the bypass pipe, wherein a first position and a second position are defined in the circulation pipe, the first pipe is a pipe connecting a downstream side of the second position and an upstream side of the first position, the second pipe is a pipe connecting a downstream side of the first position and an upstream side of the second position, and the bypass pipe is a pipe connecting the downstream side of the first position and the upstream side of the second position through a path different from a path of the second pipe.

Thus, the object of this disclosure is to provide a technology that can enhance the separation efficiency using the separation membrane.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example structure of a substrate processing apparatus;

FIG. 2 is a side view schematically illustrating an example structure of a processing unit;

FIG. 3 schematically illustrates an example structure of an organic solvent collector;

FIG. 4 is a side sectional view schematically illustrating an example structure of a dewaterer;

FIG. 5 illustrates an example procedure to be performed by the organic solvent collector;

FIG. 6 illustrates an example procedure for separating water from a mixed fluid;

FIG. 7 is a diagram for illustrating Step S1;

FIG. 8 is a diagram for illustrating Step S201;

FIG. 9 is a diagram for illustrating Step S202;

FIG. 10 is a diagram for illustrating Step S205;

FIG. 11 is a diagram for illustrating Step S207;

FIG. 12 is a diagram for illustrating Step S211;

FIG. 13 is a diagram for illustrating Step S212;

FIG. 14 is a diagram for illustrating Step S3;

FIG. 15 is a diagram for illustrating Step S4;

FIG. 16 schematically illustrates an example structure of the organic solvent collector according to a modification; and

FIG. 17 schematically illustrates an example structure of the organic solvent collector according to a modification.

### DESCRIPTION OF THE PREFERRED EMBODIMENTS

An embodiment will be described below with reference to the attached drawings. The constituent elements described in the embodiment are mere exemplification, and only the exemplification does not intend to limit the scope of the disclosure. The drawings are drawn in schematic form, structures are appropriately omitted or simplified, and the dimensions and the number of parts are illustrated in exaggeration or simplified for convenience in description. The position relationships between the structures in the drawings are not necessarily accurately illustrated.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “homogeneous”) include those indicating quantitatively exact equality and those in the presence of a difference within tolerance or to the extent that similar functions can be obtained. Unless otherwise noted, the expressions indicating shapes (e.g., “circular”, “oval”, “rectangular” or “cylindrical”) include those indicating geometrically exact shapes and those indicating, for example, roughness or a chamfer to the extent that similar advantages can be obtained. An expression “comprising”, “including”, “containing”, or “having” one or more constituent elements is not an exclusive expression for excluding the presence of the other constituent elements. An expression “at least one of A, B, or C” involves “only A”, “only B”, “only C”, “any two of A, B, and C”, and “all of A, B, and C”. Even when the ordinal numbers such as “first” and “second” are used, these terms are used for convenience to facilitate the understanding of the details of the embodiment. The order indicated by these ordinal numbers does not restrict the details of the embodiment.

### [1. Substrate Processing Apparatus]

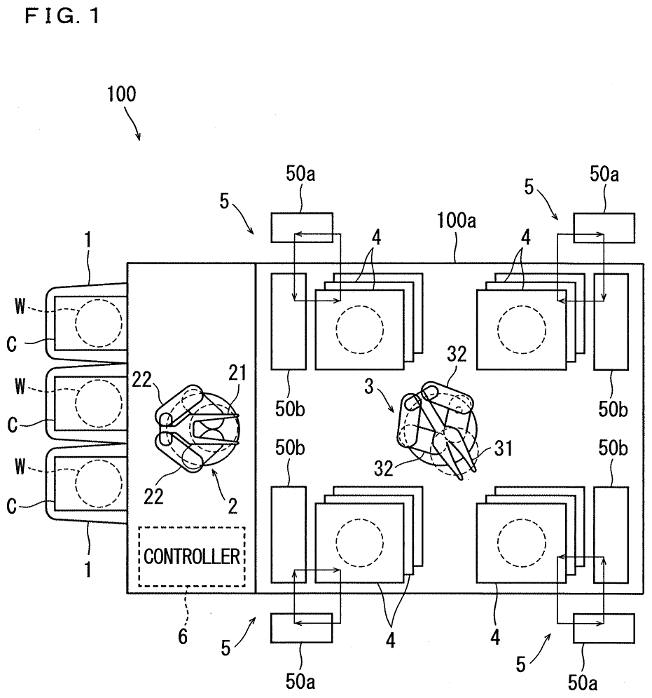

A substrate processing apparatus 100 according to the embodiment will be described with reference to FIG. 1. FIG. 1 is a plan view schematically illustrating an example structure of the substrate processing apparatus 100.

The substrate processing apparatus 100 is a single-wafer processing apparatus that processes (treats) substrates W to be processed one by one. The substrate W to be processed by the substrate processing apparatus 100 is, for example, a semiconductor substrate. The shape of the substrate W to be processed is, for example, disk-shaped.

The substrate processing apparatus 100 includes load ports 1, an indexer robot 2, a main transport robot 3, processing units 4, organic solvent collectors 5, and a controller 6.

Each of the load ports 1 is an interface for transporting the substrate W into and out of a carrier C that is a sort of a container that houses a plurality of the substrates W. The number of the load ports 1 is, for example, multiple (three in the example of the drawing). The load ports 1 are, for example, horizontally aligned in a row. The carriers C may be of a type that houses the substrates W in an airtight space (e.g., a front opening unified pod (FOUP) or a standard mechanical interface (SMIF) pod), or of a type that exposes the substrates W to outside air (e.g., an open cassette (OC)).

The indexer robot 2 is a transporter that transports the substrate W. The indexer robot 2 is, for example, a horizontal articulated robot, and includes a pair of hands 21 that hold the substrate W, and an arm 22 that is connected to each of the hands 21. Furthermore, the indexer robot 2 includes a driving mechanism (not illustrated) for rotating each of the hands 21 and flexing, rotating, and raising and lowering each of the arms 22. The indexer robot 2 transports the substrate W between each of the carriers C placed on the load ports 1 and the main transport robot 3. In other words, the indexer robot 2 accesses each of the carriers C placed on the load ports 1 to perform an unloading operation (i.e., an operation of unloading the substrate W housed in the carrier C using the hands 21) and perform a loading operation (i.e., an operation of loading the substrate W held by the hands 21 into the carrier C). Furthermore, the indexer robot 2 accesses a transfer position to transfer the substrate W to and from the main transport robot 3.

The main transport robot 3 is a transporter that transports the substrate W. The main transport robot 3 is, for example, a horizontal articulated robot, and includes a pair of hands 31 that hold the substrate W, and an arm 32 that is connected to each of the hands 31. Furthermore, the main transport robot 3 includes a driving mechanism (not illustrated) for rotating each of the hands 31 and flexing, rotating, and raising and lowering each of the arms 32. The main transport robot 3 transports the substrate W between the indexer robot 2 and each of the processing units 4. In other words, the main transport robot 3 accesses a transfer position to transfer the substrate W to and from the indexer robot 2. Furthermore, the main transport robot 3 accesses each of the processing units 4 to perform a loading operation (i.e., an operation of loading the substrate W held by the hands 31 into the processing unit 4) and perform an unloading operation (i.e., an operation of unloading the substrate W in the processing unit 4 using the hands 31).

Each of the processing units 4 subjects the substrate W to a predetermined processing using processing liquids (e.g., a chemical liquid, a rinse liquid, and an organic solvent). For example, the plurality of processing units 4 (e.g., three processing units 4) stacked in a vertical direction compose one tower. The plurality of towers (e.g., four towers in the example of the drawing) are placed around the main transport robot 3. The specific structure of the processing unit 4 will be described later.

Each of the organic solvent collectors 5 collects the organic solvent that has been used for the processing in the processing unit 4, and supplies the organic solvent to the processing unit 4 again. Here, the organic solvent collectors 5 as many as the towers are provided. The organic solvent collectors 5 correspond one-to-one with the towers. Each of the organic solvent collectors 5 collects the organic solvent that has been used for the processing in the respective processing units 4 included in the corresponding tower, and supplies the organic solvent to the respective processing units 4 included in the corresponding tower again. The specific structure of the organic solvent collector 5 will be described later.

The controller 6 controls operations of parts included in the substrate processing apparatus 100 (the load ports 1, the indexer robot 2, the main transport robot 3, the processing units 4, and the organic solvent collectors 5). The controller 6 is implemented by, for example, a common computer with an electrical circuit. The controller 6 includes, for example, a central processing unit (CPU) that performs various computation processes (data processes), a read-only memory (ROM) for storing a basic program, etc., a random access memory (RAM) used as a work area when the CPU performs a predetermined process (a data process), a storage device (specifically, for example, non-volatile storage devices such as a flash memory and a hard disk device), and a bus line that mutually connects these. The storage device or the RAM may store a program for defining processes to be executed by the controller 6. Here, for example, the CPU executes the program, so that the controller 6 may control the parts included in the substrate processing apparatus 100 and the substrate processing apparatus 100 may execute the processes defined by the program. In other words, the CPU executes the program, so that the controller 6 may implement a circuit that executes the processes defined by the program. However, hardware such as a dedicated logic circuit may execute (implement) a part or the entire control to be performed by the controller 6 (a part or the entire circuit to be implemented by the controller 6).

### [2. Processing Unit]

### [2-1. Structure of Processing Unit]

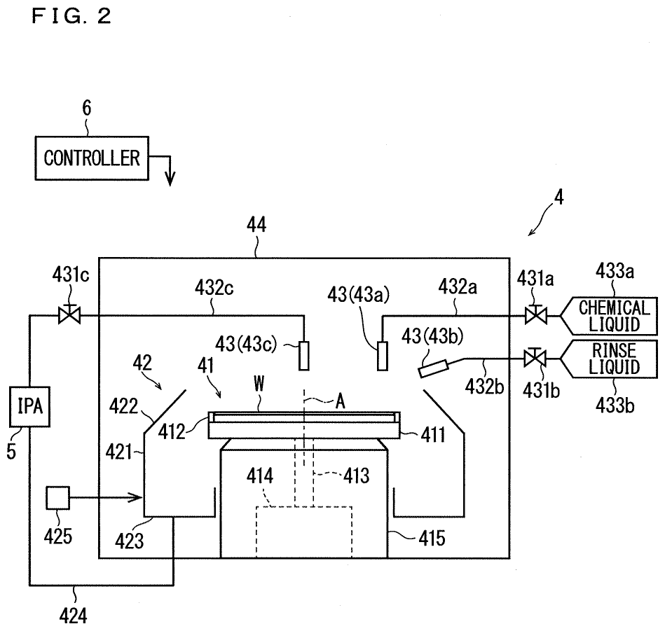

The structure of the processing unit 4 will be described below with reference to FIG. 2. FIG. 2 is a side view schematically illustrating an example structure of the processing unit 4.

Each of the processing units 4 subjects the substrate W to a predetermined processing using processing liquids (e.g., a chemical liquid, a rinse liquid, and an organic solvent). The processing unit 4 includes, for example, a spin chuck 41, a cup 42, and nozzles 43. The spin chuck 41, the cup 42, and the nozzles 43 are housed in a processing chamber 44.

The spin chuck 41 rotates the substrate W about an axis line (a rotation axis line) A that passes through the center of the main surface of the substrate W and extends in the upward and downward direction, while holding the substrate W in a horizontal attitude (an attitude with which the thickness direction of the substrate W is along the upward and downward direction (vertical direction)). The spin chuck 41 includes, specifically for example, a spin base 411. The spin base 411 is a disk-shaped part, and is disposed in an attitude such that the thickness direction is along the upward and downward direction. A plurality of chuck pins 412 are arranged on the upper surface of the spin base 411. The chuck pins 412 are arranged at regular intervals along the circumference corresponding to the outer edge of the substrate W. A linkage mechanism (not illustrated), which moves the chuck pins 412 between an abutment position and an open position, is connected to the chuck pins 412. The abutment position is a position at which the chuck pins 412 abut the outer edge of the substrate W. The open position is a position at which the chuck pins 412 are away from the outer edge of the substrate W. When each of the chuck pins 412 is disposed at the abutment position, the substrate W is held (chucked) in a horizontal attitude above the spin base 411. When each of the chuck pins 412 is disposed at the open position, hold of the substrate W is released. The linkage mechanism switches the positions of the chuck pins 412 according to an instruction from the controller 6. In other words, the controller 6 controls, for example, the timing to hold the substrate W and the timing to release the hold of the substrate W. Furthermore, the spin base 411 is connected to a spin motor 414 through a shaft 413 disposed coaxial with the rotation axis line A. The shaft 413 and the spin motor 414 are housed in a cover 415. The spin motor 414 rotates the shaft 413 about the rotation axis line A. This allows the spin base 411 and further the substrate W held above the spin base 411 to rotate about the rotation axis line A. The spin motor 414 rotates the spin base 411 according to an instruction from the controller 6. In other words, the controller 6 controls, for example, the rotation speed, the rotation start timing, and the rotation end timing of the spin base 411 (further the substrate W).

The cup 42 receives the processing liquid discharged from the substrate W that is held and rotated by the spin chuck 41. The cup 42 specifically includes, for example, a cylindrical guide part 421 disposed coaxial with the rotation axis line A, a slope 422 that is continuous from the upper end of the guide part 421 and has a diameter that becomes smaller toward the top, and a liquid receiver 423 that is continuous from the lower end of the guide part 421 and forms an annular groove that is opened upward. The liquid receiver 423 is equipped with cup-side collecting pipes that collect the liquid received herein. Here, for example, the cup-side collecting pipes include a cup-side collecting pipe for the chemical liquid (not illustrated) and a cup-side collecting pipe 424 for the organic solvent. Furthermore, a cup elevating mechanism 425 that moves the cup 42 up and down between a lower position and an upper position is connected to the cup 42. The lower position is a position at which the upper end of the cup 42 (specifically, the upper end of the slope 422) is located below the substrate W held by the spin chuck 41. The upper position is a position at which the upper end of the cup 42 is located above the substrate W held by the spin chuck 41. The cup elevating mechanism 425 moves the cup 42 up and down according to an instruction from the controller 6. In other words, the controller 6 controls the position of the cup 42.

The nozzles 43 each discharge (dispense) a processing liquid toward the upper surface of the substrate W held by the spin chuck 41. Here, for example, the nozzles 43 are separately provided for each type of processing liquids. In other words, the nozzles 43 include the nozzle 43 for discharging a chemical liquid (also hereinafter referred to as a “chemical liquid nozzle 43a”), the nozzle 43 for discharging a rinse liquid (also hereinafter referred to as a “rinse liquid nozzle 43b”), and the nozzle 43 for discharging an organic solvent (also hereinafter referred to as an “organic solvent nozzle 43c”).

The chemical liquid nozzle 43a discharges a chemical liquid toward the upper surface of the substrate W held by the spin chuck 41. The chemical liquid nozzle 43a is connected to a chemical liquid supply source 433a through a chemical liquid pipe 432a into which a chemical liquid valve 431a is inserted. Once the chemical liquid valve 431a is opened, a chemical liquid is supplied to the chemical liquid nozzle 43a through the chemical liquid pipe 432a, and the chemical liquid is discharged from the chemical liquid nozzle 43a. The chemical liquid valve 431a is opened and closed according to an instruction from the controller 6. In other words, the controller 6 controls the timing to discharge the chemical liquid from the chemical liquid nozzle 43a. The chemical liquid is, for example, fluoric acid. The chemical liquid is not limited to fluoric acid, but may be at least one of sulfuric acid, acetic acid, nitric acid, hydrochloric acid, hydrofluoric acid, phosphoric acid, ammonia water, a hydrogen peroxide solution, organic acid (e.g., citric acid and oxalic acid), organic alkali (e.g. tetramethylammonium hydroxide (TMAH)), a surface active agent, or a corrosion inhibitor.

The rinse liquid nozzle 43b discharges a rinse liquid toward the upper surface of the substrate W held by the spin chuck 41. In other words, the rinse liquid nozzle 43b functions as a rinse liquid supply nozzle (a rinse liquid supply part) that supplies a rinse liquid to the substrate W herein. The rinse liquid nozzle 43b is connected to a rinse liquid supply source 433b through a rinse liquid pipe 432b into which a rinse liquid valve 431b is inserted. Once the rinse liquid valve 431b is opened, a rinse liquid is supplied to the rinse liquid nozzle 43b through the rinse liquid pipe 432b, and the rinse liquid is discharged from the rinse liquid nozzle 43b. The rinse liquid valve 431b is opened and closed according to an instruction from the controller 6. In other words, the controller 6 controls the timing to discharge the rinse liquid from the rinse liquid nozzle 43b. Here, the rinse liquid is water (specifically, for example, pure water (deionized water)).

The organic solvent nozzle 43c discharges an organic solvent toward the upper surface of the substrate W held by the spin chuck 41. In other words, the organic solvent nozzle 43c functions as an organic solvent supply nozzle (an organic solvent supply part) that supplies an organic solvent to the substrate W herein. The organic solvent nozzle 43c is connected to the organic solvent collector 5 through an organic solvent pipe 432c into which an organic solvent valve 431c is inserted. Once the organic solvent valve 431c is opened, an organic solvent (an organic solvent with sufficiently high purity, specifically, for example, an organic solvent with purity of 99 wt % or higher) is supplied to the organic solvent nozzle 43c through the organic solvent pipe 432c, and is discharged from the organic solvent nozzle 43c. The organic solvent valve 431c is opened and closed according to an instruction from the controller 6. In other words, the controller 6 controls the timing to discharge the organic solvent from the organic solvent nozzle 43c. The organic solvent is, for example, a water-soluble organic solvent. Here, the organic solvent is isopropyl alcohol (IPA).

A nozzle movement mechanism that moves at least one of the chemical liquid nozzle 43a, the rinse liquid nozzle 43b, or the organic solvent nozzle 43c between a processing position and a retracted position may be connected to the at least one nozzle. The processing position is a position at which the processing liquid discharged from the nozzle 43a, 43b, or 43c is supplied to the substrate W held by the spin chuck 41. The retracted position is a position of the nozzle 43a, 43b, or 43c that is located outside of the outer edge of the substrate W held by the spin chuck 41 (outward in a radial direction) when viewed from the top. Here, the nozzle movement mechanism moves the nozzle 43a, 43b, or 43c according to an instruction from the controller 6. In other words, the controller 6 controls the positions of the nozzle 43a, 43b, and 43c.

### [2-2. Operations of Processing Unit]

Example operations of the processing unit 4 will be described with reference to FIG. 2 again.

The operations of the processing unit 4 are performed under control of the controller 6. In other words, the controller 6 controls, for example, the chuck pins 412, the spin motor 414, the cup elevating mechanism 425, the chemical liquid valve 431a, the rinse liquid valve 431b, and the organic solvent valve 431c, so that the processing unit 4 proceeds with a series of the operations.

Once the main transport robot 3 transports the substrate W into the processing chamber 44, the spin chuck 41 holds the substrate W. Then, the spin chuck 41 starts rotating.

In this state, the chemical liquid valve 431a is opened. Then, the chemical liquid nozzle 43a discharges the chemical liquid toward the upper surface of the substrate W held and rotated by the spin chuck 41. This supplies the chemical liquid to the entire region of the upper surface of the substrate W to process the substrate W with the chemical liquid (a chemical liquid supplying step). For example, when fluoric acid is used as the chemical liquid, the chemical liquid removes a foreign substance such as particles from the substrate W. During the chemical liquid supplying step, the cup 42 is located at the upper position. Thus, the cup 42 receives the chemical liquid scattered around the substrate W. In other words, the chemical liquid scattered around the substrate W is received by the slope 422, is guided downward by the guide part 421, and is collected by the liquid receiver 423. The chemical liquid received by the cup 42 (i.e., the chemical liquid collected by the liquid receiver 423) is collected through the cup-side collecting pipe (not illustrated) for the chemical liquid.

After a lapse of a predetermined time since start of discharging the chemical liquid, the chemical liquid valve 431a is closed. Then, the chemical liquid nozzle 43a stops discharging the chemical liquid. Next, the rinse liquid valve 431b is opened. Then, the rinse liquid nozzle 43b discharges the rinse liquid toward the upper surface of the substrate W held and rotated by the spin chuck 41. This supplies the rinse liquid to the entire region of the upper surface of the substrate W to rinse out the chemical liquid that adheres to the substrate W with the rinse liquid (a rinse liquid supplying step). During the rinse liquid supplying step, the cup 42 is also located at the upper position. Thus, the cup 42 receives the chemical liquid and the rinse liquid scattered around the substrate W. The chemical liquid and the rinse liquid received by the cup 42 are collected through the cup-side collecting pipe (not illustrated) for the chemical liquid.

After a lapse of a predetermined time since start of discharging the rinse liquid, the rinse liquid valve 431b is closed. Then, the rinse liquid nozzle 43b stops discharging the rinse liquid. Next, the organic solvent valve 431c is opened. Then, the organic solvent nozzle 43c discharges IPA toward the upper surface of the substrate W held and rotated by the spin chuck 41. This supplies IPA to the entire region of the upper surface of the substrate W to replace the rinse liquid that adheres to the substrate W with IPA (an organic solvent supplying step). During the organic solvent supplying step, the cup 42 is also located at the upper position. Thus, the cup 42 receives the rinse liquid and the IPA scattered around the substrate W. The rinse liquid and the IPA received by the cup 42 are collected through the cup-side collecting pipe 424 for the organic solvent.

After a lapse of a predetermined time since start of supplying IPA, the organic solvent valve 431c is closed. Then, the organic solvent nozzle 43c stops discharging IPA. In this phase, the rinse liquid on the substrate W is completely replaced with IPA, and a liquid film of IPA covering the entire region of the upper surface of the substrate W is formed. Next, the spin chuck 41 starts rotating at high speeds. This allows the substrate W to rotate at high speeds to throw off the IPA on the substrate W around the substrate W by centrifugal force (a spin drying step). While the substrate W is rotated at high speeds, the cup 42 is also located at the upper position. Thus, the cup 42 receives the IPA scattered around the substrate W. The IPA received by the cup 42 is collected through the cup-side collecting pipe 424 for the organic solvent.

After a lapse of a predetermined time since the spin chuck 41 starts rotating at high speeds, the rotation of the spin chuck 41 is stopped. In this phase, the IPA is removed from the substrate W, and the substrate W is dried. The main transport robot 3 transports the dried substrate W out of the processing chamber 44.

As described above, a series of processes on the single substrate W is completed. In the processing unit 4, the aforementioned series of processes is repeated to process the substrates W one by one.

### [3. Organic Solvent Collector]

### [3-1. Structure]

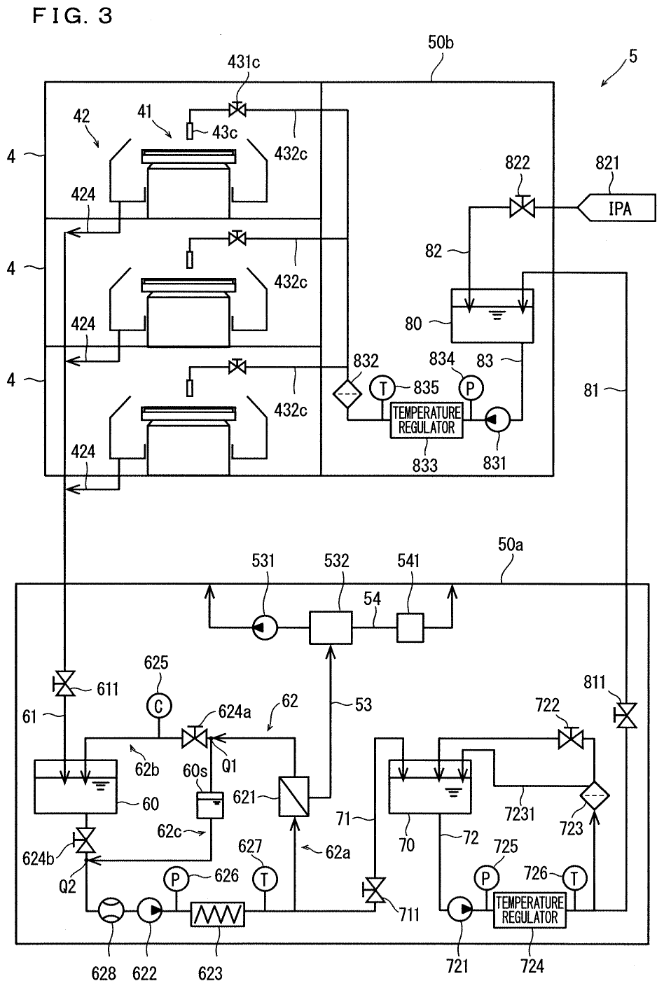

The structure of the organic solvent collector 5 will be described with reference to FIG. 3. FIG. 3 schematically illustrates an example structure of the organic solvent collector 5.

The organic solvent collector 5 includes a collection tank 60, a purification tank 70, and a supply tank 80. For example, a first storage box 50a houses the collection tank 60 and the purification tank 70, and a second storage box 50b houses the supply tank 80. For example, the first storage box 50a is disposed outside an external wall 100a of the substrate processing apparatus 100 (e.g., under a clean room in which the substrate processing apparatus 100 is installed (underground)), and the second storage box 50b is disposed inside the external wall 100a of the substrate processing apparatus 100 (FIG. 1).

### (a) Collection Tank 60

The collection tank 60 is connected to the cups 42 through a collection pipe 61. In other words, one end of the collection pipe 61 is connected to the collection tank 60, and the other end of the collection pipe 61 is connected to the cups 42 (specifically, the cup-side collecting pipes 424 connected to the cups 42). Here, for example, the collection pipe 61 is connected to the cup 42 included in each of the processing units 4 belonging to the same tower. A collection valve 611 is disposed in the collection pipe 61. Once the collection valve 611 is opened, the organic solvent (IPA herein) collected by the cups 42 in the organic solvent supplying step and the spin drying step is guided by the collection pipe 61, and flows into and is stored by the collection tank 60. The IPA (IPA with sufficiently high purity, specifically, for example, IPA with purity of 99 wt % or higher) is collected in the spin drying step, whereas IPA in a state where the IPA is mixed with the rinse liquid (water herein) (i.e., a state of being diluted with water) is collected in the organic solvent supplying step. Thus, the collection tank 60 stores a mixed fluid containing the water supplied to the substrate W and then collected in the processing unit 4 and the IPA supplied to the substrate W and then collected in the processing unit 4.

A circulation pipe (a dewatering circulation pipe) 62 is connected to the collection tank 60. Specifically, both of one end and the other end of the dewatering circulation pipe 62 are connected to the collection tank 60. The dewatering circulation pipe 62 forms a circulation path through which the mixed fluid stored in the collection tank 60 circulates by flowing out of the collection tank 60 and returning to the collection tank 60 again.

A dewaterer (separator) 621 is disposed in the dewatering circulation pipe 62. The dewaterer 621 separates water from the mixed fluid flowing into the dewaterer 621 to dewater the mixed fluid. The structure of the dewaterer 621 will be described later.

The dewatering circulation pipe 62 includes a first pipe (hereinafter referred to as a first piping portion 62a), a second pipe (hereinafter referred to as a second piping portion 62b), and a bypass pipe (hereinafter referred to as a bypass piping portion 62c). In other words, a first position Q1 and a second position Q2 are defined in the dewatering circulation pipe 62. The first piping portion 62a is a pipe (a piping portion) connecting a downstream side of the second position Q2 and an upstream side of the first position Q1. The second piping portion 62b is a pipe (a piping portion) connecting a downstream side of the first position Q1 and an upstream side of the second position Q2. The bypass piping portion 62c is a pipe (a piping portion) connecting the downstream side of the first position Q1 and the upstream side of the second position Q2 through a path different from that of the second piping portion 62b. For example, the dewaterer 621 is disposed in the first piping portion 62a herein. In other words, the second position Q2 is defined downstream of the first position Q1 and upstream of the dewaterer 621. Furthermore, for example, the collection tank 60 is disposed in the second piping portion 62b herein. In other words, the first position Q1 is located downstream of the dewaterer 621 and upstream of the collection tank 60, and the second position Q2 is located downstream of the collection tank 60 and upstream of the dewaterer 621.

A pump (a dewatering feed pump) 622 and a heater 623 are disposed in the dewatering circulation pipe 62. For example, both of the dewatering feed pump 622 and the heater 623 are disposed in the first piping portion 62a herein. For example, the heater 623 is disposed upstream of the dewaterer 621, and the dewatering feed pump 622 is disposed upstream of the heater 623.

The dewatering feed pump 622 feeds the mixed fluid in the dewatering circulation pipe 62 at a pressure necessary for circulation (a circulation pressure P1). Furthermore, the dewatering feed pump 622 pressurizes the mixed fluid at a separation pressure P2 that is higher than the circulation pressure P1 (P1<P2). As will be described later, the higher the separation pressure P2 is, the more the separation efficiency of separating water in the dewaterer 621 is increased. Also, the higher the separation pressure P2 is, the more a heating temperature T2 can be increased. The higher the heating temperature T2 is, the more the separation efficiency is increased, which will be described later. Thus, the separation pressure P2 is preferably as high as possible within a range not exceeding pressure resistance values of a piping portion through which the pressurized mixed fluid flows and the devices disposed in the piping portion.

The heater 623 heats the mixed fluid to the predetermined heating temperature T2. Here, the heating temperature T2 is a temperature higher than a boiling point (a normal boiling point) T1 of an organic solvent (IPA herein) at atmospheric pressure, and lower than a boiling point (a pressurized boiling point) T3 of the organic solvent (IPA herein) at the separation pressure P2 (T1<T2<T3). As will be described later, the higher the heating temperature T2 is, the more the separation efficiency of separating water in the dewaterer 621 is increased. On the other hand, when the temperature of the mixed fluid exceeds the boiling point of IPA, the IPA that accounts for most of the mixed fluid is brought to a boil, and very high pressure may be suddenly applied to the piping portion through which the mixed fluid flows and the devices disposed in the piping portion. Here, the boiling point of IPA is increased to the pressurized boiling point T3 higher than the normal boiling point T1 by pressurizing the mixed fluid at the separation pressure P2 (i.e., the separation pressure P2 predefined in consideration of the pressure resistance value of, for example, the piping portion through which the mixed fluid flows). Therefore, even when the mixed fluid is heated to a temperature higher than the normal boiling point T1, the IPA contained in the mixed fluid does not boil as long as the temperature does not exceed the pressurized boiling point T3. In other words, the mixed fluid can be heated to a temperature higher than the normal boiling point T1, without bringing the IPA contained in the mixed fluid to a boil. This can enhance the separation efficiency. Obviously, the higher the separation pressure P2 is, the higher the pressurized boiling point T3 becomes, and the more the heating temperature T2 can be increased.

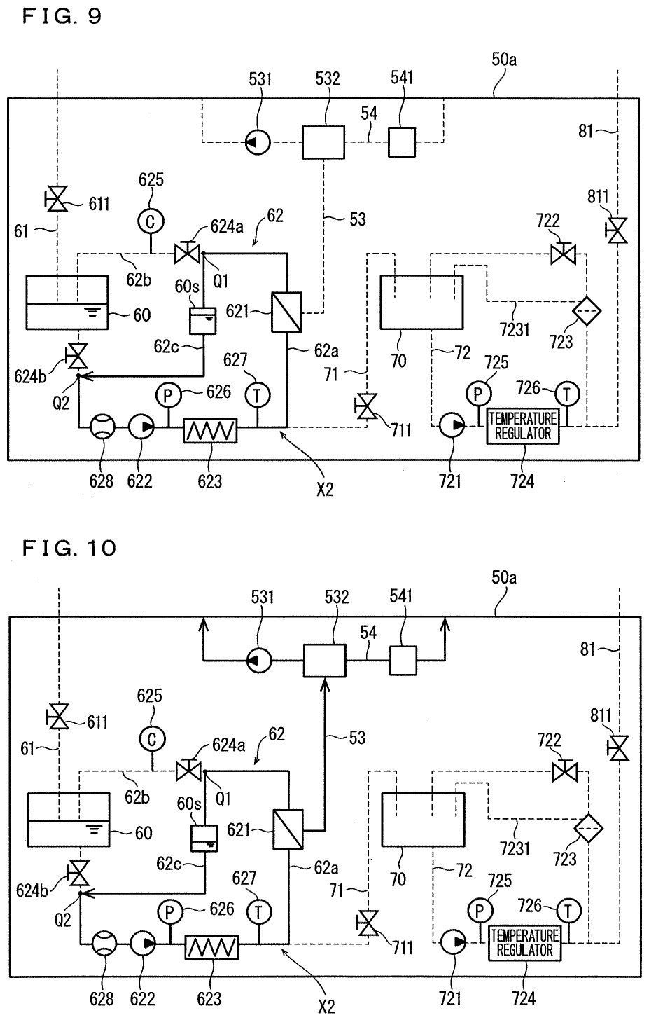

Switching valves (selector valves) 624a and 624b are disposed in the dewatering circulation pipe 62. The switching valves 624a and 624b switch between a state in which a fluid circulates through the first piping portion 62a, the second piping portion 62b, and the bypass piping portion 62c (a first circulating state X1) (FIG. 8) and a state in which a fluid circulates through the first piping portion 62a and the bypass piping portion 62c (a second circulating state X2) (FIG. 9). Here, for example, the first switching valve 624a is disposed in the vicinity of the upstream end (the first position Q1) in the second piping portion 62b, and the second switching valve 624b is disposed in the vicinity of the downstream end (the second position Q2) in the second piping portion 62b. When the dewatering feed pump 622 is operated with the pair of switching valves 624a and 624b being opened, the fluid circulates through the first piping portion 62a, the second piping portion 62b, and the bypass piping portion 62c. In other words, the first circulating state X1 is created. On the other hand, when the dewatering feed pump 622 is operated with the pair of switching valves 624a and 624b being closed, the fluid circulates through the first piping portion 62a and the bypass piping portion 62c. In other words, the second circulating state X2 is created.

Here, the dewatering feed pump 622 pressurizes the mixed fluid at the separation pressure P2, in a state where the mixed fluid circulates through the first piping portion 62a and the bypass piping portion 62c (the second circulating state X2). Similarly, the heater 623 heats the mixed fluid to the heating temperature T2 in the second circulating state X2. Thus, the pressurized and heated mixed fluid flows through the first piping portion 62a and the bypass piping portion 62c, and the pressurized and heated mixed fluid does not flow through the second piping portion 62b (strictly speaking, a piping portion downstream of the first switching valve 624a and upstream of the second switching valve 624b in the second piping portion 62b).

Thus, although the first piping portion 62a, the bypass piping portion 62c, and the devices disposed in these piping portions (e.g., the dewaterer 621, the dewatering feed pump 622, and the heater 623) have pressure resistance that can withstand the separation pressure P2 and have heat resistance that can withstand the heating temperature T2, the second piping portion 62b (strictly speaking, the piping portion downstream of the first switching valve 624a and upstream of the second switching valve 624b in the second piping portion 62b) and the devices disposed in this piping portion (e.g., the collection tank 60) need not have pressure resistance that can withstand the separation pressure P2 and have heat resistance that can withstand the heating temperature T2. In other words, the second piping portion 62b and the devices disposed in this piping portion may be lower in pressure resistance and heat resistance than the first piping portion 62a, the bypass piping portion 62c, and the devices disposed in these piping portions. For example, the first piping portion 62a and the bypass piping portion 62c are formed using pressure-resistance pipes (e.g., metal pipes), and the piping portion downstream of the first switching valve 624a and upstream of the second switching valve 624b in the second piping portion 62b is formed using a pipe that is not a pressure-resistance pipe (e.g., a resin pipe). Furthermore, the collection tank 60 need not be a pressure vessel (a pressure tank), and is, for example, an atmospheric pressure tank.

A buffer tank 60s that stores the mixed fluid is disposed in the dewatering circulation pipe 62. The buffer tank 60s is disposed in the first piping portion 62a or the bypass piping portion 62c (the bypass piping portion 62c in the example of the drawing). As will be described later, the dewaterer 621 separates water from the mixed fluid in the second circulating state X2 where the mixed fluid circulates through the first piping portion 62a and the bypass piping portion 62c. During this operation, the mixed fluid with the amount corresponding to the separated water is refilled from the buffer tank 60s into the pipe, so that a state where the mixed fluid circulates through the first piping portion 62a and the bypass piping portion 62c is maintained. The buffer tank 60s does not require the capacity as much as that of the collection tank 60. In other words, the capacity of the buffer tank 60s may be smaller than that of the collection tank 60. Specifically, the buffer tank 60s may have a capacity such that at least the minimum mixed fluid necessary for maintaining the circulation can be stored in a completed state of separating water from the mixed fluid circulating through the first piping portion 62a and the bypass piping portion 62c (specifically, a state after circulation of the mixed fluid through the first piping portion 62a and the bypass piping portion 62c during operation of the vacuum pump 531 is continued for a predetermined time and a state where the concentrated fluid circulates through the first piping portion 62a and the bypass piping portion 62c as will be described later). The buffer tank 60s has pressure resistance that can withstand the separation pressure P2 and has heat resistance that can withstand the heating temperature T2. For example, the buffer tank 60s is a pressure vessel (a pressure tank).

Various sensors may be disposed in the dewatering circulation pipe 62. For example, a concentration sensor 625 that measures the concentration of IPA contained in the mixed fluid that circulates through the dewatering circulation pipe 62, a pressure sensor 626 that detects the pressure of the mixed fluid that circulates through the dewatering circulation pipe 62, a temperature sensor 627 that detects the temperature of the mixed fluid that circulates through the dewatering circulation pipe 62, and a flow rate sensor (flowmeter) 628 that measures the flow rate of the mixed fluid that circulates through the dewatering circulation pipe 62 may be disposed in the dewatering circulation pipe 62. If sensors with, for example, pressure resistance that can withstand the separation pressure P2 and heat resistance that can withstand the heating temperature T2 can be employed as the sensors 625, 626, 627, and 628, the sensors may be disposed in the first piping portion 62a or the bypass piping portion 62c. If employing such sensors is difficult, the sensors are disposed in the second piping portion 62b. In the example of the drawing, the concentration sensor 625 is disposed in the second piping portion 62b, whereas the pressure sensors 626, the temperature sensor 627, the flow rate sensor 628 are disposed in the first piping portion 62a. In the example of the drawing, the concentration sensor 625 is disposed in the vicinity downstream of the first position Q1, the pressure sensor 626 is disposed in the vicinity downstream of the dewatering feed pump 622, the temperature sensor 627 is disposed in the vicinity downstream of the heater 623, and the flow rate sensor 628 is disposed in the vicinity upstream of the dewatering feed pump 622.

### (b) Dewaterer 621

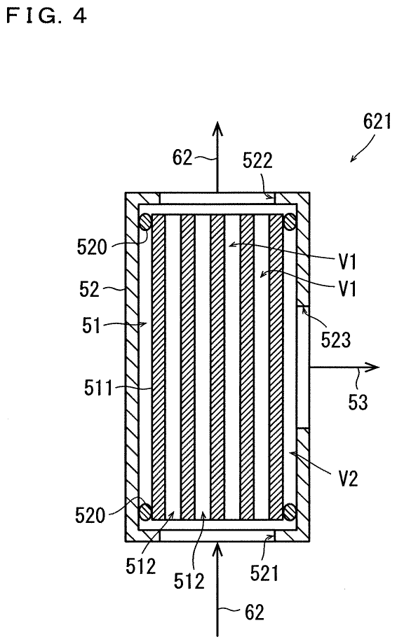

Next, the dewaterer 621 will be described with reference to FIG. 4 in addition to FIG. 3. FIG. 4 is a side sectional view schematically illustrating an example structure of the dewaterer 621.

The dewaterer 621 includes a separation membrane 51 and a housing 52.

The separation membrane 51 is a membrane that allows water to pass through and does not allow an organic solvent (IPA herein) to pass through (the separation membrane 51 blocks the passage of the organic solvent). The separation membrane 51 is, specifically for example, a zeolite membrane made of zeolite. Zeolite has, for example, a crystal structure in which base units of a tetrahedral structure (e.g., base units each including at least one of (SiO₄)⁴⁻ or (AlO₄)⁵⁻) are mutually coupled. The separation membrane 51 has, specifically for example, a structure including a myriad of cells 512 penetrating a cylindrical base body 511 in an axis direction. The cells 512 form the flow paths of the mixed fluid in the separation membrane 51. The entire base body 511 may be made of zeolite or only the inner circumferential surface of each of the cells 512 may be made of zeolite.

The housing 52 is a hollow and cylindrical component, and houses the separation membrane 51 inside. A pair of sealants 520 which seals a portion between the housing 52 and the separation membrane 51 housed in the housing 52 is provided between the housing 52 and the separation membrane 51. Each of the pairs of sealants 520 is, for example, ring-shaped, and is disposed at one end and the other end of the separation membrane 51 in the axis direction. The internal space of the housing 52 is separated by the separation membrane 51 into a cell internal space V1 that is an internal space of the separation membrane 51 (i.e., an internal space of the cells 512), and a separation space V2 that is an external space of the separation membrane 51. Furthermore, the housing 52 has an inlet 521, a first outlet 522, and a second outlet 523. The inlet 521 is disposed at one end face of the housing 52 in the axis direction, and communicates with the cell internal space V1 through one opening of each of the cells 512. The first outlet 522 is disposed at the other end face of the housing 52 in the axis direction, and communicates with the cell internal space V1 through the other opening of each of the cells 512. The second outlet 523 is disposed at the side surface (a peripheral surface) of the housing 52, and communicates with the separation space V2.

The dewatering circulation pipe 62 is connected to the inlet 521 and the first outlet 522. A separation pipe 53 equipped with a vacuum pump 531 is connected to the second outlet 523. The mixed fluid flowing through the dewatering circulation pipe 62 flows from the inlet 521 into the dewaterer 621 (specifically, the cell internal space V1) and flows through the cell internal space V1. Once the vacuum pump 531 disposed in the separation pipe 53 operates in this state, the pressure in the separation space V2 is reduced to provide a pressure difference between the cell internal space V1 and the separation space V2. The separation membrane 51 that separates the cell internal space V1 from the separation space V2 is a membrane that allows water to pass through and does not allow IPA to pass through. Thus, when the pressure difference is provided between the cell internal space V1 and the separation space V2, water (water molecules) contained in the mixed fluid flowing into the cell internal space V1 passes through the separation membrane 51, reaches the separation space V2, and flows into the separation pipe 53 through the second outlet 523. In this manner, water is separated from the mixed fluid. In contrast, since IPA (IPA molecules) contained in the mixed fluid flowing into the cell internal space V1 cannot pass through the separation membrane 51, the IPA flows through the cell internal space V1, and flows into the dewatering circulation pipe 62 through the first outlet 522. As such, the mixed fluid containing the IPA with a concentration higher than that when entering the dewaterer 621 flows out of the dewaterer 621. Each time the mixed fluid repeatedly passes through the dewaterer 621, the concentration of the IPA in the mixed fluid increases.

Here, the mixed fluid flowing into the dewaterer 621 is pressurized at the separation pressure P2 and heated to the heating temperature T2. When the pressurized mixed fluid flows into the cell internal space V1, a pressure difference between the cell internal space V1 and the separation space V2 increases more than that when a non-pressurized mixed fluid flows into the cell internal space V1. Consequently, the number of water molecules that pass through the separation membrane 51 per unit time increases. Furthermore, when the mixed fluid is heated, the average kinetic energy of water molecules contained in the mixed fluid increases more than that when the mixed fluid is not heated. Consequently, the number of water molecules that pass through the separation membrane 51 per unit time increases. Thus, pressurizing and heating the mixed fluid flowing into the dewaterer 621 enhances the separation efficiency (dewatering efficiency).

A structure on the separation pipe 53 side into which water separated from the mixed fluid flows can be appropriately defined. Here, for example, a condenser 532 is disposed upstream of the vacuum pump 531 in the separation pipe 53. A waste pipe 54 guiding the water condensed by the condenser 532 is connected to the condenser 532. The waste pipe 54 is equipped with a decomposer 541 that decomposes the organic solvent (IPA herein) contained in trace amounts in water flowing through the waste pipe 54 to increase the purity of water. The decomposer 541 may increase the purity of water, for example, through electrolysis of IPA contained in water. The decomposer 541 herein can include, for example, a tank that temporarily stores water flowing through the waste pipe 54, a pair of electrodes to be soaked in the water stored in the tank, and a power supply part that supplies power to the pair of electrodes to produce a potential difference between the electrodes. The waste pipe 54 may be connected to, for example, the rinse liquid supply source 433b (FIG. 2) of the processing unit 4 or a water collection line in a factory. For example, when the waste pipe 54 is connected to the rinse liquid supply source 433b, the water separated from the mixed fluid and flowing into the separation pipe 53 is condensed by the condenser 532 and flows into the waste pipe 54. The water that flows into the waste pipe 54 increases its purity at the decomposer 541, and the water is guided through the waste pipe 54 to the rinse liquid supply source 433b and discharged from the rinse liquid nozzle 43b as a rinse liquid. In other words, the water separated from the mixed fluid is recycled as a rinse liquid herein.

### (c) Purification Tank 70

FIG. 3 is again referred to. The purification tank 70 is connected to the collection tank 60 through a first feed pipe 71 and the dewatering circulation pipe 62. In other words, one end of the first feed pipe 71 is connected to the purification tank 70, and the other end of the first feed pipe 71 is connected to the dewatering circulation pipe 62. For example, the other end of the first feed pipe 71 is connected to the first piping portion 62a of the dewatering circulation pipe 62 (e.g., at a position downstream of the heater 623 and upstream of the dewaterer 621 in the first piping portion 62a). A first feed valve 711 is disposed in the first feed pipe 71. When the first piping portion 62a and the bypass piping portion 62c store a fluid in which the concentration (purity) of IPA has been sufficiently increased (the concentration of IPA is high enough to be supplied to the substrate W) (hereinafter also referred to as a “concentrated fluid”) by separating water from the mixed fluid, once the first feed valve 711 is opened, the concentrated fluid is guided by the first feed pipe 71, and flows into and is stored by the purification tank 70.

A circulation pipe (a purifying circulation pipe) 72 is connected to the purification tank 70. Specifically, both of one end and the other end of the purifying circulation pipe 72 are connected to the purification tank 70. The purifying circulation pipe 72 forms a circulation path through which the concentrated fluid stored in the purification tank 70 circulates by flowing out of the purification tank 70 and returning to the purification tank 70 again.

A pump (a purifying feed pump) 721 and an open/close valve 722 are disposed in the purifying circulation pipe 72. For example, the open/close valve 722 is disposed downstream of the purifying feed pump 721 and upstream of the purification tank 70. The purifying feed pump 721 feeds the concentrated fluid in the purifying circulation pipe 72 at a pressure necessary for circulation. The purifying feed pump 721 feeds the concentrated fluid at the pressure necessary for circulation with the open/close valve 722 being opened, so that the concentrated fluid stored in the purification tank 70 circulates through the purifying circulation pipe 72.

A filter 723 and a temperature regulator 724 are disposed in the purifying circulation pipe 72. For example, the filter 723 is disposed downstream of the purifying feed pump 721 and upstream of the purification tank 70. The temperature regulator 724 is disposed downstream of the purifying feed pump 721 and upstream of the filter 723. The filter 723 captures a removal target substance (e.g., particles and a metal) contained in the concentrated fluid flowing through the purifying circulation pipe 72. Passage of the concentrated fluid through the filter 723 removes the removal target substance contained in the concentrated fluid from the concentrated fluid, and increases the cleanliness of the concentrated fluid. An air removal pipe 7231 may be connected to the filter 723. The temperature regulator 724 is a device with a cooling capacity and a heating capacity, and is, for example, an electronic cooler/heater that electronically cools and heats an object using a Peltier element. When a fluid at a high temperature passes through the filter 723, for example, thermal expansion may cause a decrease in the performance of the filter 723. Thus, the temperature regulator 724 herein cools the concentrated fluid circulating through the purifying circulation pipe 72 to a predetermined temperature (e. g., room temperature) as necessary. This suppresses the decrease in the performance of the filter 723.

Various sensors may be disposed in the purifying circulation pipe 72. For example, a pressure sensor 725 that detects a pressure of the concentrated fluid circulating through the purifying circulation pipe 72, a temperature sensor 726 that detects the temperature of the concentrated fluid circulating through the purifying circulation pipe 72, and a particle counter (not illustrated) that counts the number of particles contained in the concentrated fluid circulating through the purifying circulation pipe 72 may be disposed in the purifying circulation pipe 72. In the example of the drawing, the pressure sensor 725 is disposed in the vicinity downstream of the purifying feed pump 721, and the temperature sensor 726 is disposed in the vicinity downstream of the temperature regulator 724.

### (d) Supply Tank 80

The supply tank 80 is connected to the purification tank 70 through a second feed pipe 81 and the purifying circulation pipe 72. In other words, one end of the second feed pipe 81 is connected to the supply tank 80, and the other end of the second feed pipe 81 is connected to the purifying circulation pipe 72. For example, the other end of the second feed pipe 81 is connected to a position upstream of the filter 723 and downstream of the purifying feed pump 721 in the purifying circulation pipe 72. However, the other end of the second feed pipe 81 may be directly connected to the purification tank 70, not through the purifying circulation pipe 72. A second feed valve 811 is disposed in the second feed pipe 81. When the purification tank 70 stores the concentrated fluid in which the cleanliness has been sufficiently increased (the cleanliness is high enough to be supplied to the substrate W) (hereinafter also referred to as a “purified fluid”), once the second feed valve 811 is opened, the purified fluid is guided by the second feed pipe 81, and flows into and is stored by the supply tank 80.

The supply tank 80 may be connected to a new liquid supply source 821 through a new liquid pipe 82. Here, one end of the new liquid pipe 82 is connected to the supply tank 80, and the other end of the new liquid pipe 82 is connected to the new liquid supply source 821. The new liquid supply source 821 is a supply source of unused IPA that has not yet been supplied to the substrate W (IPA with sufficiently high purity, specifically for example, IPA with purity of 99 wt % or higher). A new liquid valve 822 is disposed in the new liquid pipe 82. Once the new liquid valve 822 is opened, the unused IPA is guided by the new liquid pipe 82, and flows into and is stored by the supply tank 80.

The supply tank 80 is connected to the organic solvent nozzles 43c through a third feed pipe 83. In other words, one end of the third feed pipe 83 is connected to the supply tank 80, and the other end of the third feed pipe 83 is connected to the organic solvent nozzles 43c (specifically, the organic solvent pipes 432c connected to the organic solvent nozzles 43c). Here, for example, the third feed pipe 83 is connected to the organic solvent nozzles 43c included in each of the processing units 4 belonging to the same tower. A pump (a supplying feed pump) 831 is disposed in the third feed pipe 83. Once the organic solvent valves 431c are opened, the purified fluid stored in the supply tank 80 is fed by the supplying feed pump 831 to the organic solvent nozzles 43c side, and is discharged from the organic solvent nozzles 43c.

A filter 832 and a temperature regulator 833 may be disposed in the third feed pipe 83. The filter 832 captures a removal target substance contained in the purified fluid fed through the third feed pipe 83. The temperature regulator 833 regulates the temperature of the purified fluid fed through the third feed pipe 83 (i.e., heats or cools the purified fluid to a predetermined temperature). In the example of the drawing, the temperature regulator 833 is disposed downstream of the supplying feed pump 831, and the filter 832 is disposed downstream of the temperature regulator 833. Furthermore, various sensors may be disposed in the third feed pipe 83. For example, a pressure sensor 834 that detects a pressure of the purified fluid fed through the third feed pipe 83, and a temperature sensor 835 that detects the temperature of the purified fluid fed through the third feed pipe 83 may be disposed in the third feed pipe 83. In the example of the drawing, the pressure sensor 834 is disposed in the vicinity downstream of the supplying feed pump 831, and the temperature sensor 835 is disposed in the vicinity downstream of the temperature regulator 833.

### [3-2. Operations]

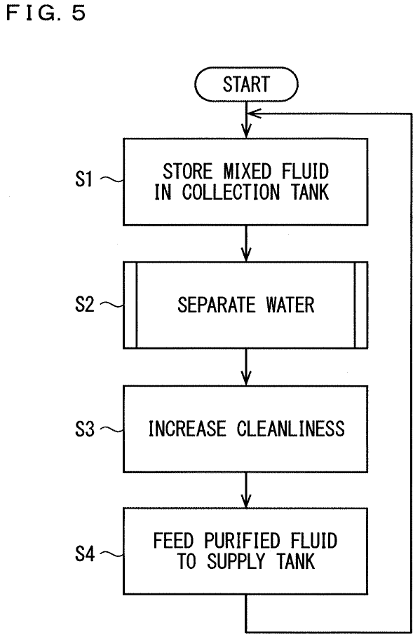

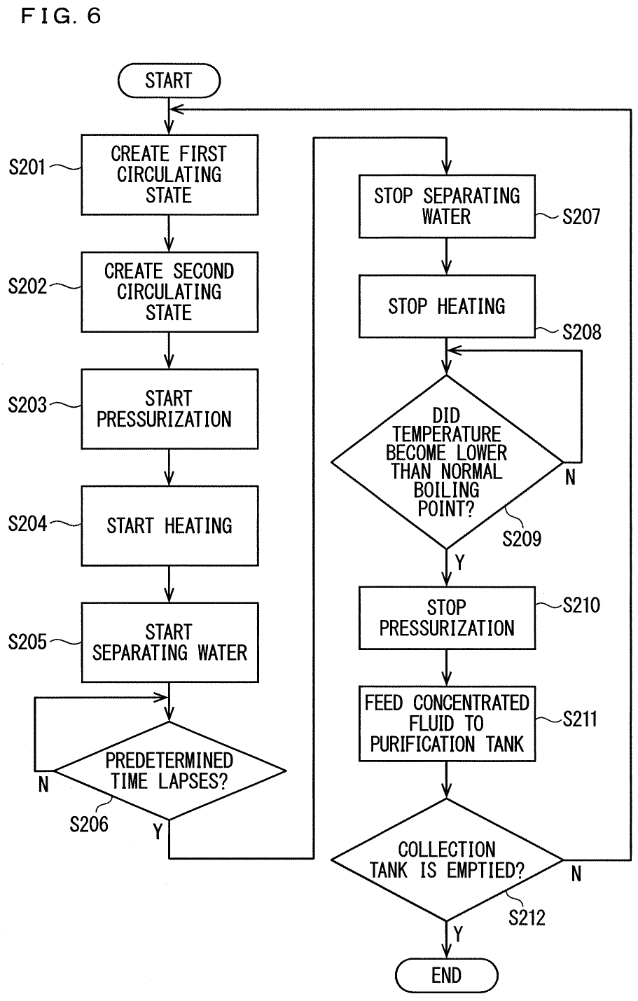

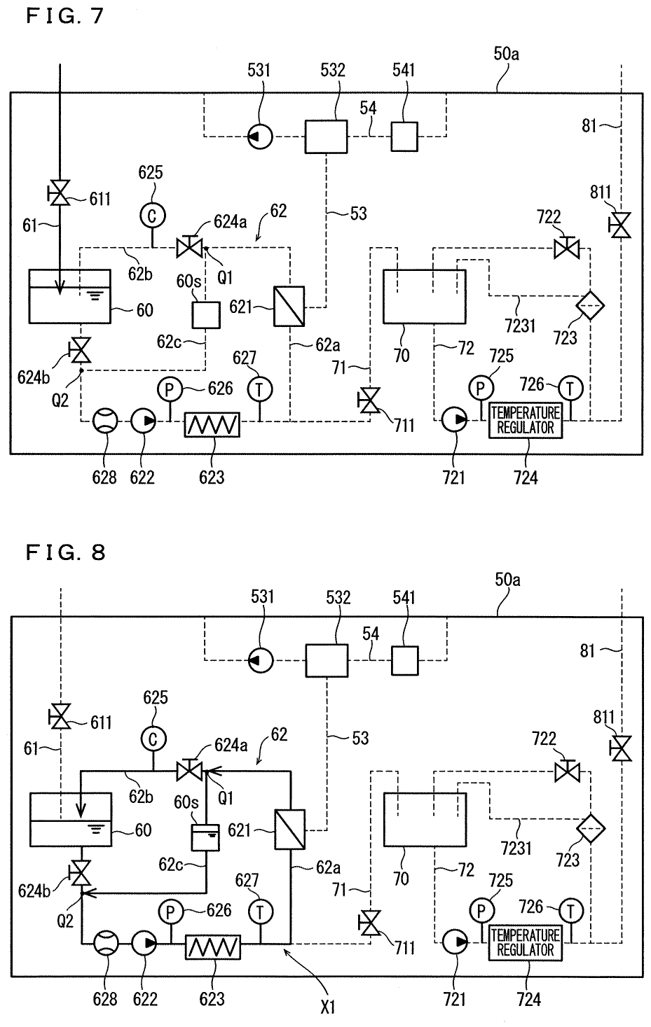

The procedure to be performed by the organic solvent collector 5 will be described with reference to FIGS. 5 to 14. FIG. 5 illustrates an example procedure to be performed by the organic solvent collector 5. FIG. 6 illustrates an example procedure for separating water from a mixed fluid. FIGS. 7 to 14 schematically illustrate a state of the organic solvent collector 5 in each step. In FIGS. 7 to 14, a solid line indicates a pipe through which a fluid flows, and a dashed line indicates a pipe through which a fluid does not flow for convenience in description.

The operations of the organic solvent collector 5 are performed under control of the controller 6. In other words, the controller 6 controls, for example, pumps (the dewatering feed pump 622, the vacuum pump 531, the purifying feed pump 721, and the supplying feed pump 831), valves (the collection valve 611, the pair of switching valves 624a and 624b, the first feed valve 711, the open/close valve 722, the second feed valve 811, and the new liquid valve 822, etc.), the heater 623, the condenser 532, the decomposer 541, and the temperature regulators 724 and 833, based on information input from sensors (the concentration sensor 625, the pressure sensors 626, 725, and 834, the temperature sensors 627, 726, and 835, and the flow rate sensor 628), so that the organic solvent collector 5 proceeds with a series of the operations.

### Step S1

First, the collection valve 611 is opened with the collection tank 60 being empty. Then, the liquid collected by the cups 42 in the organic solvent supplying step and the spin drying step is guided by the collection pipe 61, and flows into the collection tank 60. Consequently, the collection tank 60 stores the mixed fluid containing the water supplied to the substrate W and then collected and the IPA supplied to the substrate W and then collected (FIG. 7) (a storing step). When the collection tank 60 stores a predetermined quantity of the mixed fluid, the collection valve 611 is closed.

### Step S2

Then, a process of separating water from the mixed fluid stored in the collection tank 60 is performed. This process will be specifically described with reference to FIGS. 6 and 8 to 13.

First, the dewatering feed pump 622 feeds the mixed fluid at the circulation pressure P1 with the pair of switching valves 624a and 624b being opened. For example, the circulation pressure P1 is 0.1 MPa or higher and 0.2 MPa or lower. This fills the first piping portion 62a, the second piping portion 62b, the bypass piping portion 62c, and the buffer tank 60s with the mixed fluid stored in the collection tank 60 to create a state in which the mixed fluid circulates through the first piping portion 62a, the second piping portion 62b, and the bypass piping portion 62c (the first circulating state X1) (Step S201: a filling step) (FIG. 8). Here, the mixed fluid flows through the first piping portion 62a, and branches off at the first position Q1 to a route flowing through the second piping portion 62b (i.e., a route passing through the collection tank 60) and a route flowing through the bypass piping portion 62c (i.e., a route without passing through the collection tank 60). Then, the mixed fluids flowing through the respective routes merge at the second position Q2 to flow through the first piping portion 62a again.

Then, the pair of switching valves 624a and 624b is closed while the circulation pressure P1 is maintained. This isolates the second piping portion 62b to create a state in which the mixed fluid circulates through the first piping portion 62a and the bypass piping portion 62c (the second circulating state X2) (Step S202: a circulating step) (FIG. 9). Here, the mixed fluid flowing through the first piping portion 62a flows into the bypass piping portion 62c at the first position Q1 and flows through the bypass piping portion 62c. Then, the mixed fluid flows into the first piping portion 62a at the second position Q2 again and flows through the first piping portion 62a.

Next, pressurizing the mixed fluid is started (Step S203: a pressurizing step). Specifically, the pressure of the dewatering feed pump 622 is switched from the circulation pressure P1 to the separation pressure P2. This pressurizes the mixed fluid circulating through the first piping portion 62a and the bypass piping portion 62c at the separation pressure P2. For example, the separation pressure P2 is preferably 0.5 MPa or higher, and is particularly preferably 1.0 MPa or higher. Then, heating the mixed fluid is started (Step S204: a heating step). Specifically, the heater 623 heats the mixed fluid circulating through the first piping portion 62a and the bypass piping portion 62c to the heating temperature T2. The heating temperature T2 is preferably 100° C. or higher, and is particularly preferably 120° C. or higher. Here, in a state where the mixed fluid circulates through the first piping portion 62a and the bypass piping portion 62c (the second circulating state X2), after the dewatering feed pump 622 pressurizes the mixed fluid at the separation pressure P2 (i.e., after the boiling point of IPA is increased to the pressurized boiling point T3), the heater 623 heats the mixed fluid to the heating temperature T2. Thus, IPA is not brought to a boil during the heating (during rising of the temperature).

Then, the vacuum pump 531 starts to operate while the mixed fluid continues to be pressurized and heated. Once the vacuum pump 531 operates, the pressure in the separation space V2 is reduced to provide a pressure difference between the cell internal space V1 and the separation space V2. This pressure difference allows water contained in the mixed fluid flowing into the cell internal space V1 to pass through the separation membrane 51, reach the separation space V2, and flow into the separation pipe 53. In other words, when the mixed fluid circulating through the first piping portion 62a and the bypass piping portion 62c flows into and passes through the dewaterer 621, water contained in the mixed fluid is separated (Step S205: a separation step) (FIG. 10). Here, since the mixed fluid flowing into the dewaterer 621 has been pressurized at the separation pressure P2 and heated to the heating temperature T2, water is efficiently separated from the mixed fluid. Since the pressurized mixed fluid flows into the cell internal space V1, a certain pressure difference is created between the cell internal space V1 and the separation space V2 in a state prior to operations of the vacuum pump 531 (i.e., a state where the vacuum pump 531 is not operated and the pressurized mixed fluid flows into the dewaterer 621). Thus, some separation of water still occurs even in this state. Further, the operations of the vacuum pump 531 from such a state sufficiently increase the pressure difference, and promote the separation of water.

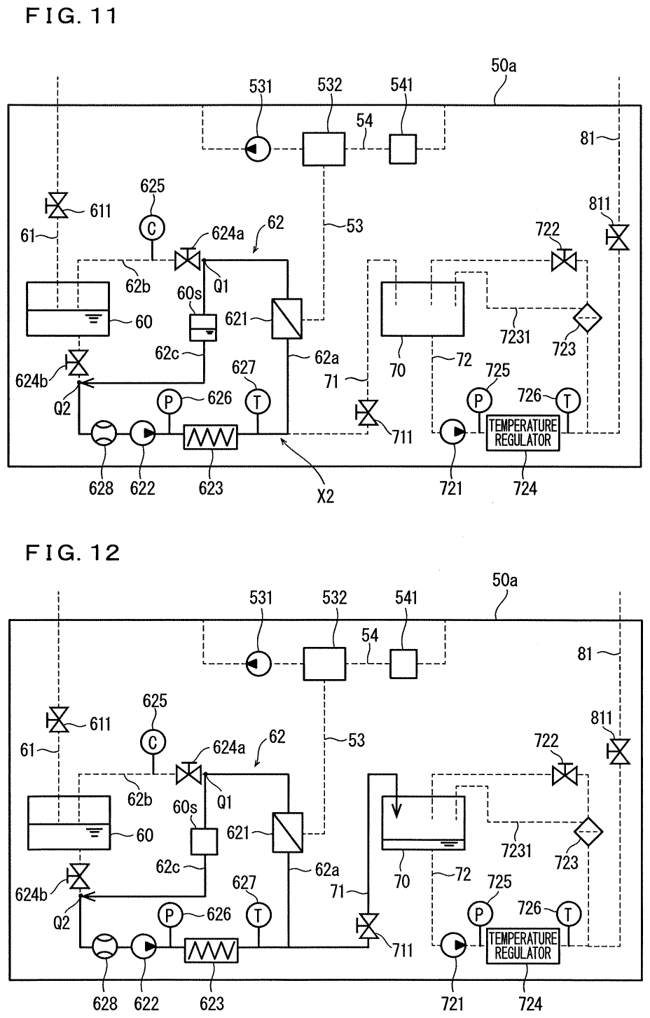

Then, a state where the vacuum pump 531 is operating is continued only for a predetermined time. During this time, the mixed fluid continues to be pressurized and heated. Meanwhile, the mixed fluid circulating through the first piping portion 62a and the bypass piping portion 62c repeatedly passes through the dewaterer 621, which increases the concentration of IPA in the mixed fluid. During this operation, the mixed fluid with the amount corresponding to the separated water is refilled from the buffer tank 60s into the pipe, so that a state where the mixed fluid circulates through the first piping portion 62a and the bypass piping portion 62c is maintained. Here, the time required to sufficiently increase the concentrations of IPA in the mixed fluid circulating through the first piping portion 62a and the bypass piping portion 62c and the mixed fluid stored in the buffer tank 60s (the concentrations are high enough to supply the fluid to the substrate W), that is, the time required to obtain the concentrated fluid is determined in advance through, for example, measurement and calculation, and is defined as the predetermined time. Thus, after a lapse of the predetermined time since start of operating the vacuum pump 531, the concentrated fluid circulates through the first piping portion 62a and the bypass piping portion 62c and is stored in the buffer tank 60s. After a lapse of the predetermined time since start of operating the vacuum pump 531 (YES in Step S206), the operation of the vacuum pump 531 is stopped. As a result, water separation in the dewaterer 621 is almost stopped (Step S207) (FIG. 11).

Next, heating the concentrated fluid is stopped (Step S208). Specifically, the heater 623 stops the heating (Step S208). Then, lowering the temperature of the concentrated fluid circulating through the first piping portion 62a and the bypass piping portion 62c to a temperature lower than the normal boiling point T1 (82.3° C. in IPA) is waited (Step S209). When the temperature of the concentrated fluid becomes lower than the normal boiling point T1 (YES in Step S209), pressurizing the concentrated fluid is stopped (Step S210). Specifically, the pressure of the dewatering feed pump 622 is switched from the separation pressure P2 to the circulation pressure P1. Here, in a state where the concentrated fluid circulates through the first piping portion 62a and the bypass piping portion 62c, the heater 623 stops heating the concentrated fluid, and after the temperature of the concentrated fluid becomes lower than the normal boiling point T1, the dewatering feed pump 622 stops pressurizing the concentrated fluid. In other words, until the temperature of the concentrated fluid is lowered to the temperature lower than the normal boiling point T1, the pressurizing state is maintained. Thus, IPA is not brought to a boil during lowering of the temperature.

Then, the first feed valve 711 is opened. This allows the concentrated fluid in the first piping portion 62a, the bypass piping portion 62c, and the buffer tank 60s to be fed to the purification tank 70 through the first feed pipe 71. Thus, the concentrated fluid is stored in the purification tank 70 (Step S211) (FIG. 12).

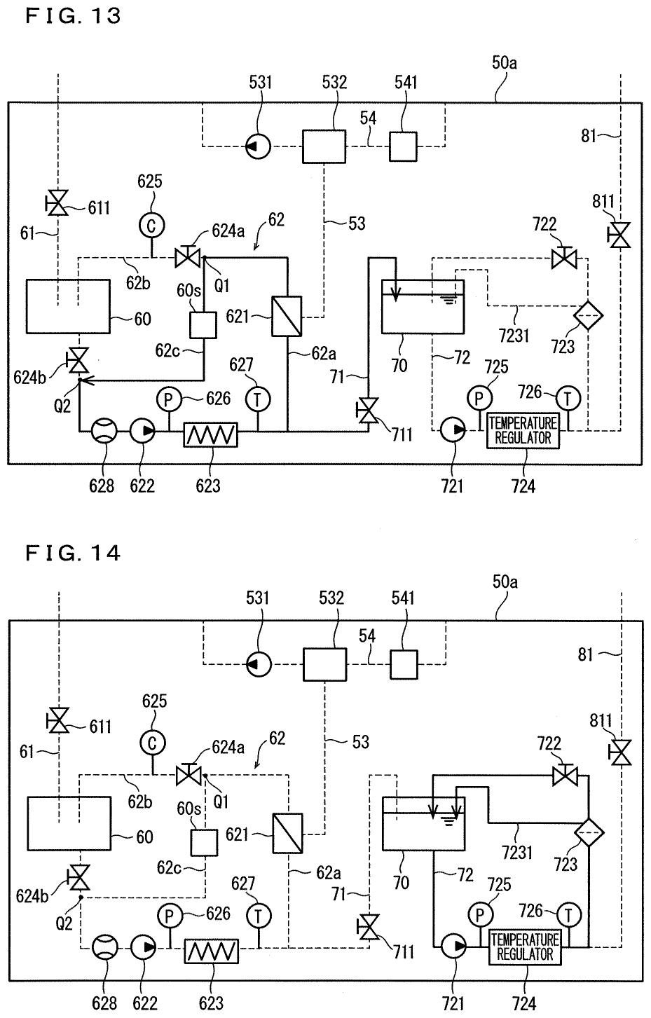

Then, processes in Steps S201 to 211 are repeated again. As the number of repetitions increases, the amount of the mixed fluid stored in the collection tank 60 decreases, and the amount of the concentrated fluid stored in the purification tank 70 increases. When the collection tank 60 is emptied (YES in Step S212), (FIG. 13), the process in Step S2 (i.e., a process of separating water from the mixed fluid stored in the collection tank 60) is terminated. Obviously, when the amount of the mixed fluid remaining in the collection tank 60 becomes sufficiently less, assuming that the collection tank 60 is emptied, the process in Step S2 may be terminated.

### Step S3

Next, a process of increasing the cleanliness of the concentrated fluid stored in the purification tank 70 is performed. Specifically, the open/close valve 722 is opened, and the purifying feed pump 721 feeds the concentrated fluid at the pressure necessary for circulation. This allows the concentrated fluid stored in the purification tank 70 to circulate through the purifying circulation pipe 72 (FIG. 14). This state is continued only for a predetermined time. Meanwhile, the concentrated fluid circulating through the purifying circulation pipe 72 repeatedly passes through the filter 723, which increases the cleanliness of the concentrated fluid. Here, the time required to sufficiently increase the cleanliness of the concentrated fluid circulating through the purifying circulation pipe 72 (the cleanliness is high enough to supply the fluid to the substrate W), that is, the time required to obtain the purified fluid is determined in advance through, for example, measurement and calculation, and is defined as the predetermined time. Thus, after a lapse of the predetermined time since start of the circulation, the purified fluid is stored in the purification tank 70. After a lapse of the predetermined time since start of the circulation, the open/close valve 722 is closed.

### Step S4

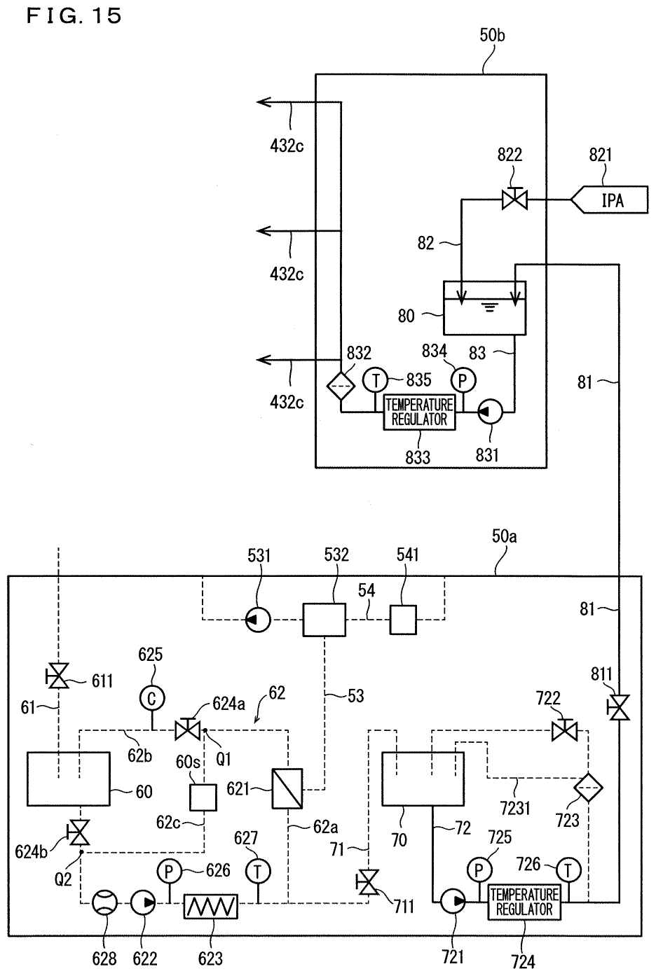

Next, the second feed valve 811 is opened. This allows the purified fluid in the purification tank 70 to be fed to the supply tank 80 through the second feed pipe 81. Thus, the purified fluid is stored in the supply tank 80 (FIG. 15). For example, when the total quantity of the purified fluid in the purification tank 70 is fed to the supply tank 80, the second feed valve 811 is closed. Then, once the organic solvent valves 431c are opened, the purified fluid stored in the supply tank 80 is fed by the supplying feed pump 831 to the organic solvent nozzles 43c side, and is discharged from the organic solvent nozzles 43c. In other words, the purified fluid is supplied to the substrates W. At some midpoint of the passage through the third feed pipe 83, the purified fluid may pass through the filter 832 to increase the cleanliness, or the temperature of the purified fluid may be regulated by the temperature regulator 833 as necessary. Furthermore, when the quantity of the purified fluid stored in the supply tank 80 is less than a predetermined quantity, the new liquid valve 822 may be opened to refill unused IPA in the supply tank 80.

In the organic solvent collector 5, the aforementioned series of processes (Steps S1 to S4) is repeated. However, a process in next Step S1 may be performed prior to the end of the process in Step S4 (e.g., at the completion of the process in Step S3).

### [4. Advantages]

The substrate processing apparatus 100 according to the embodiment above includes: a rinse liquid supply nozzle (the rinse liquid nozzle 43b) that supplies the substrate W with a rinse liquid containing water; an organic solvent supply nozzle (the organic solvent nozzle 43c) that supplies an organic solvent (e.g., IPA) to the substrate W; the collection tank 60 that stores a mixed fluid containing the water supplied to the substrate W and then collected and the organic solvent supplied to the substrate W and then collected; a circulation pipe (the dewatering circulation pipe 62) connected to the collection tank 60; the dewaterer 621 disposed in the dewatering circulation pipe 62 and including the separation membrane 51 that allows the water to pass through and does not allow the organic solvent to pass through; a pump (the dewatering feed pump 622) disposed in the dewatering circulation pipe 62; and the heater 623 disposed in the dewatering circulation pipe 62. Furthermore, the first position Q1 and the second position Q2 are defined in the dewatering circulation pipe 62, and the dewatering circulation pipe 62 includes: the first pipe (the first piping portion 62a) connecting a downstream side of the second position Q2 and an upstream side of the first position Q1; the second pipe (the second piping portion 62b) connecting a downstream side of the first position Q1 and an upstream side of the second position Q2; and the bypass pipe (the bypass piping portion 62c) connecting the downstream side of the first position Q1 and the upstream side of the second position Q2 through a path different from a path of the second piping portion 62b. The dewaterer 621 is disposed in the first piping portion 62a or the bypass piping portion 62c, and the dewatering feed pump 622 pressurizes the mixed fluid at the separation pressure P2 higher than the circulation pressure P1 necessary for circulation and the heater 623 heats the mixed fluid to the predetermined heating temperature T2, in a state where the mixed fluid circulates through the first piping portion 62a and the bypass piping portion 62c.

Since this structure allows the pressurized and heated mixed fluid to flow into the dewaterer 621, water can be efficiently separated from the mixed fluid. Furthermore, the pressurized and heated mixed fluid does not flow through the second piping portion 62b under this structure, the second piping portion 62b and the devices disposed in this piping portion need not have pressure resistance equivalent to that of the first piping portion 62a, the bypass piping portion 62c, and the devices disposed in these piping portions (i.e., pressure resistance that can withstand the separation pressure P2 higher than the circulation pressure P1). This can make the apparatus more compact while enhancing the separation efficiency.

Furthermore, the collection tank 60 is disposed in the second piping portion 62b in the embodiment above. The pressurized and heated mixed fluid does not flow into the collection tank 60 under this structure. Thus, the collection tank 60 need not have pressure resistance that can withstand the separation pressure P2. This allows a vessel except a pressure vessel (a pressure tank), for example, an atmospheric pressure tank to be used as the collection tank 60, and can make the collection tank 60 more compact.

Furthermore, the heating temperature T2 is higher than the boiling point (normal boiling point) T1 of an organic solvent (e.g., IPA) at atmospheric pressure and is lower than a boiling point (the pressurized boiling point) T3 of the organic solvent at the separation pressure P2 in the embodiment above. This structure can sufficiently increase the temperature of the mixed fluid without bringing the organic solvent to a boil. This can achieve the high separation efficiency while ensuring safety.

Furthermore, in a state where the mixed fluid circulates through the first piping portion 62a and the bypass piping portion 62c (the second circulating state X2), after the dewatering feed pump 622 pressurizes the mixed fluid at the separation pressure P2, the heater 623 heats the mixed fluid to the heating temperature T2 in the embodiment above. Since the heater 623 heats the mixed fluid after the boiling point is increased by pressurizing the mixed fluid under this structure, the organic solvent is not brought to a boil during the heating.

In the embodiment above, in a state where the concentrated fluid being obtained by separating the water from the mixed fluid circulates through the first piping portion 62a and the bypass piping portion 62c (the second circulating state X2), the heater 623 stops heating the concentrated fluid, and after the temperature of the concentrated fluid becomes lower than the boiling point of the organic solvent at atmospheric pressure, the dewatering feed pump 622 stops pressurizing the concentrated fluid. Since the pressurized state is maintained until the temperature of the concentrated fluid is lowered to a temperature lower than the boiling point (normal boiling point) T1 of the organic solvent at atmospheric pressure under this structure, the organic solvent is not brought to a boil during lowering of the temperature.

The substrate processing apparatus 100 according to the embodiment above includes the vacuum pump 531 that reduces a pressure of a space (the separation space) V2 in the dewaterer 621 into which water that has passed through the separation membrane 51 flows. Reducing the pressure in the separation space V2 can promote the separation of water under this structure.

Furthermore, the substrate processing apparatus 100 according to the embodiment above includes: the purification tank 70 connected to the collection tank 60 through the dewatering circulation pipe 62 and a feed pipe (the first feed pipe 71) and storing a concentrated fluid obtained by separating water from the mixed fluid; and the filter 723 disposed in a pipe (the purifying circulation pipe 72) connected to the purification tank 70 and capturing a removal target substance contained in the concentrated fluid flowing through the purifying circulation pipe 72. This structure can increase the cleanliness of the concentrated fluid obtained by separating water from the mixed fluid, by removing the removal target substance from the concentrated fluid.

In the embodiment above, the concentrated fluid stored in the purification tank 70 is fed to the organic solvent nozzles 43c through the filter 723, and is supplied to the substrates W. In other words, after the cleanliness of the concentrated fluid obtained by separating water from the mixed fluid containing the water supplied to the substrate W and then collected and the organic solvent supplied to the substrate W and then collected is increased, the concentrated fluid is again supplied to the substrates W. Thus, the amounts of the organic solvent to be used and to be discharged can be reduced (saving liquid). IPA is a volatile organic compound (VOC), so reduction of the amounts of IPA to be used and to be discharged can mitigate the environmental load. [5. Modifications]

The structure and operations of the substrate processing apparatus 100 according to the embodiment above can be appropriately modified. In the following description, the same reference numerals are assigned to the same elements described in the embodiment above, and the description thereof will be omitted.

[5-1. First modification]

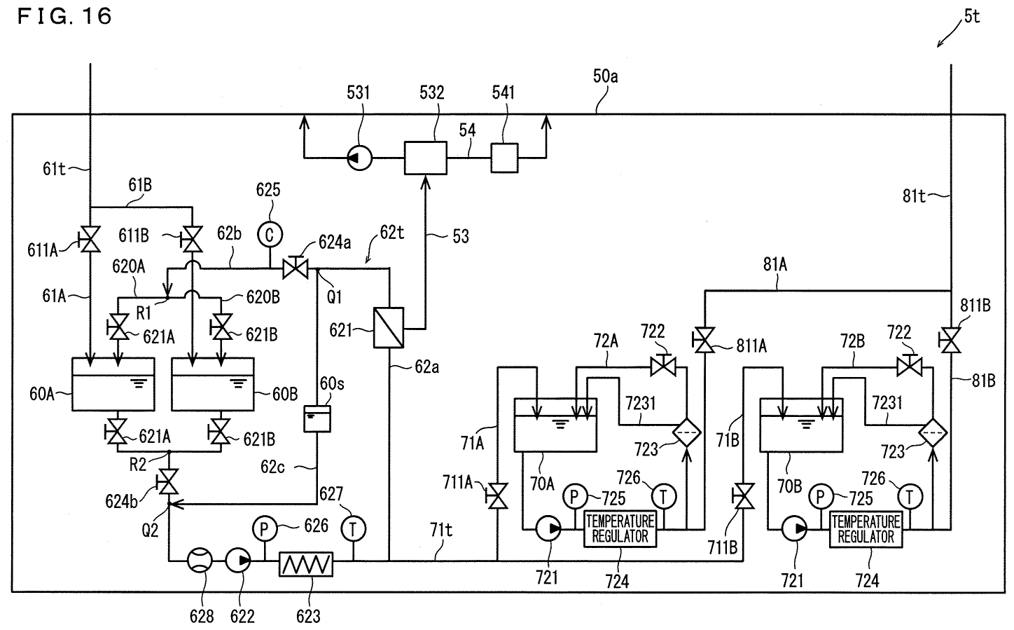

The structure of an organic solvent collector 5t according to the first modification will be described with reference to FIG. 16. FIG. 16 schematically illustrates an example of the organic solvent collector 5t.

The organic solvent collector 5t includes a plurality of (two in the example of the drawing) collection tanks 60A and 60B, a plurality of (two in the example of the drawing) purification tanks 70A and 70B, and the supply tank 80 (see FIG. 3).

The collection tanks 60A and 60B are connected to the cups 42 through a collection pipe 61t. In other words, one end of the collection pipe 61t branches off, so that an end of a branched portion 61A is connected to the first collection tank 60A, and an end of a branched portion 61B is connected to the second collection tank 60B. The other end of the collection pipe 61t is connected to the cups 42 (specifically, the cup-side collecting pipes 424 connected to the cups 42). A collection valve 611A and a collection valve 611B are disposed in the branched portion 61A and the branched portion 61B, respectively. Once the collection valve 611A is opened, the liquid collected by the cups 42 in the organic solvent supplying step and the spin drying step is guided by the collection pipe 61t, and flows into and is stored by the first collection tank 60A. In other words, the mixed fluid is stored in the first collection tank 60A. Similarly, once the other collection valve 611B is opened, the liquid collected by the cups 42 in the organic solvent supplying step and the spin drying step is guided by the collection pipe 61t, and flows into and is stored by the second collection tank 60B. In other words, the mixed fluid is stored in the second collection tank 60B.

A circulation pipe (a dewatering circulation pipe) 62t is connected to the collection tanks 60A and 60B. A branching position R1 and a merging position R2 are defined in the dewatering circulation pipe 62t. A plurality of branch pipes 620A and 620B (as many as the collection tanks 60A and 60B) are provided between the branching position R1 and the merging position R2. Furthermore, the collection tanks 60A and 60B are disposed in the branch pipes 620A and 620B, respectively. In other words, the one branch pipe 620A is provided with the first collection tank 60A, and the other branch pipe 620B is provided with the second collection tank 60B. Furthermore, a pair of first valves 621A is disposed in the branch pipe 620A, and the first collection tank 60A is sandwiched between the pair of first valves 621A. A pair of second valves 621B is disposed in the other branch pipe 620B, and the second collection tank 60B is sandwiched between the pair of second valves 621B. Once the pair of first valves 621A is opened and the pair of second valves 621B is closed, a circulation path is formed in which the mixed fluid stored in the first collection tank 60A circulates by flowing out of the first collection tank 60A and returning to the first collection tank 60A again. Conversely, once the pair of first valves 621A is closed and the pair of second valves 621B is opened, a circulation path is formed in which the mixed fluid stored in the second collection tank 60B circulates by flowing out of the second collection tank 60B and returning to the second collection tank 60B again.

Similarly to the embodiment above, the dewatering circulation pipe 62t includes the first piping portion 62a, the second piping portion 62b, and the bypass piping portion 62c. Similarly to the embodiment above, the dewaterer 621, the dewatering feed pump 622, and the heater 623 are disposed in the first piping portion 62a, and the buffer tank 60s is disposed in the bypass piping portion 62c. Furthermore, for example, the collection tanks 60A and 60B are both disposed in the second piping portion 62b herein. In other words, the first position Q1 is defined (located) downstream of the dewaterer 621 and upstream of the branching position R1, and the second position Q2 is defined (located) downstream of the merging position R2 and upstream of the dewaterer 621. The various sensors 625, 626, 627, and 628 may be disposed in the dewatering circulation pipe 62t, similarly to the embodiment above.

The switching valves 624a and 624b are disposed in the dewatering circulation pipe 62t, similarly to the embodiment above. The switching valves 624a and 624b switch between a state in which a fluid circulates through the first piping portion 62a, the second piping portion 62b, and the bypass piping portion 62c (the first circulating state X1) and a state in which a fluid circulates through the first piping portion 62a and the bypass piping portion 62c (the second circulating state X2). Furthermore, the dewatering feed pump 622 pressurizes the mixed fluid at the separation pressure P2, in a state where the mixed fluid circulates through the first piping portion 62a and the bypass piping portion 62c (the second circulating state X2), similarly to the embodiment above. Similarly, the heater 623 heats the mixed fluid to the heating temperature T2 in the second circulating state X2. Thus, although the first piping portion 62a, the bypass piping portion 62c, and the devices disposed in these piping portions (e.g., the dewaterer 621, the dewatering feed pump 622, the heater 623, and the buffer tank 60s) have pressure resistance that can withstand the separation pressure P2 and have heat resistance that can withstand the heating temperature T2, the second piping portion 62b (strictly speaking, the piping portion downstream of the first switching valve 624a and upstream of the second switching valve 624b in the second piping portion 62b) and the devices disposed in this piping portion (e.g., the collection tanks 60A and 60B) need not have pressure resistance that can withstand the separation pressure P2 and have heat resistance that can withstand the heating temperature T2. For example, the first collection tank 60A and the second collection tank 60B are atmospheric pressure tanks.

The purification tanks 70A and 70B are connected to the collection tanks 60A and 60B through a first feed pipe 71t and the dewatering circulation pipe 62t. In other words, one end of the first feed pipe 71t branches off, so that an end of a branched portion 71A is connected to the first purification tank 70A, and an end of a branched portion 71B is connected to the second purification tank 70B. The other end of the first feed pipe 71t is connected to the first piping portion 62a of the dewatering circulation pipe 62t. A first feed valve 711A and a first feed valve 711B are disposed in the branched portion 71A and the branched portion 71B, respectively. When the first piping portion 62a and the bypass piping portion 62c store the concentrated fluid, once the first feed valve 711A on the first purification tank 70A side is opened, the concentrated fluid is guided by the first feed pipe 71t, and flows into and is stored by the first purification tank 70A. Similarly, when the first piping portion 62a and the bypass piping portion 62c store the concentrated fluid, once the first feed valve 711B on the second purification tank 70B side is opened, the concentrated fluid is guided by the first feed pipe 71t, and flows into and is stored by the second purification tank 70B.

Circulation pipes (purifying circulation pipes) 72A and 72B are connected to the first purification tank 70A and the second purification tank 70B, respectively. Similarly to the purifying circulation pipe 72 according to the embodiment above, the purifying feed pump 721, the open/close valve 722, the filter 723, the temperature regulator 724, and the various sensors 725 and 726 are disposed in each of the purifying circulation pipes 72A and 72B.

The first purification tank 70A and the second purification tank 70B are connected to the supply tank 80 (FIG. 3) through the purifying circulation pipes 72A and 72B, respectively, and through a second feed pipe 81t. In other words, one end of the second feed pipe 81t branches off, so that an end of a branched portion 81A is connected to the purifying circulation pipe 72A on the first purification tank 70A side, and an end of a branched portion 81B is connected to the purifying circulation pipe 72B on the second purification tank 70B side. The other end of the second feed pipe 81t is connected to the supply tank 80. A second feed valve 811A and a second feed valve 811B are disposed in the branched portion 81A and the branched portion 81B, respectively. When the first purification tank 70A stores the purified fluid, once the second feed valve 811A on the first purification tank 70A side is opened, the purified fluid in the first purification tank 70A is guided by the second feed pipe 81t, and flows into and is stored by the supply tank 80. Similarly, when the second purification tank 70B stores the purified fluid, once the second feed valve 811B on the second purification tank 70B side is opened, the purified fluid in the second purification tank 70B is guided by the second feed pipe 81t, and flows into and is stored by the supply tank 80.

The organic solvent collector 5t also performs the series of processes (Steps S1 to S4 in FIG. 5) similarly to the embodiment above.

In other words, similarly to the embodiment above, in the organic solvent collector 5t, the liquid collected by the cups 42 is first fed to one of the collection tanks (e.g., the first collection tank 60A), and the mixed fluid is stored by the first collection tank 60A (Step S1). Then, a process of separating water from the mixed fluid stored in the first collection tank 60A is performed (Step S2). However, in the organic solvent collector 5t, in parallel with this process, the liquid collected by the cups 42 is fed to the other collection tank (the second collection tank 60B), and the mixed fluid is stored by the second collection tank 60B. In other words, after the liquid collected by the cups 42 is fed to the first collection tank 60A, the liquid collected by the cups 42 is fed to the second collection tank 60B without waiting for emptying the first collection tank 60A (i.e., without waiting for the end of the process of separating water from the mixed fluid stored in the first collection tank 60A).

Similarly to the embodiment above, in the organic solvent collector 5t, the concentrated fluid obtained by separating water from the mixed fluid is fed to the first purification tank 70A or the second purification tank 70B, and is stored by the first purification tank 70A or the second purification tank 70B. Once the concentrated fluid is stored by each of the first purification tank 70A and the second purification tank 70B, the process of increasing the cleanliness of the concentrated fluid is performed (Step S3), and the resulting purified fluid is fed to the supply tank 80 (Step S4). Since the plurality of purification tanks 70A and 70B are provided, even when the process of increasing the cleanliness of the concentrated fluid is performed in the one purification tank 70A, the concentrated fluid can be fed to the other purification tank 70B.

Since the organic solvent collector 5t includes the plurality of collection tanks 60A and 60B, switching between the collection tanks 60A and 60B that are feeding destinations can feed the liquid collected by the cups 42 (i.e., the water supplied to the substrate W and then collected and the organic solvent supplied to the substrate W and then collected) without interruption. Furthermore, since the organic solvent collector 5t includes the plurality of purification tanks 70A and 70B, switching between the purification tanks 70A and 70B that are feeding destinations can feed the concentrated fluid obtained by separating water from the mixed fluid without interruption. These can shorten the cycle time from collecting the organic solvent supplied to the substrate W until supplying the organic solvent again to the substrate W. Consequently, the amounts of the organic solvent to be used and to be discharged can be effectively reduced.

### [5-2. Second Modification]

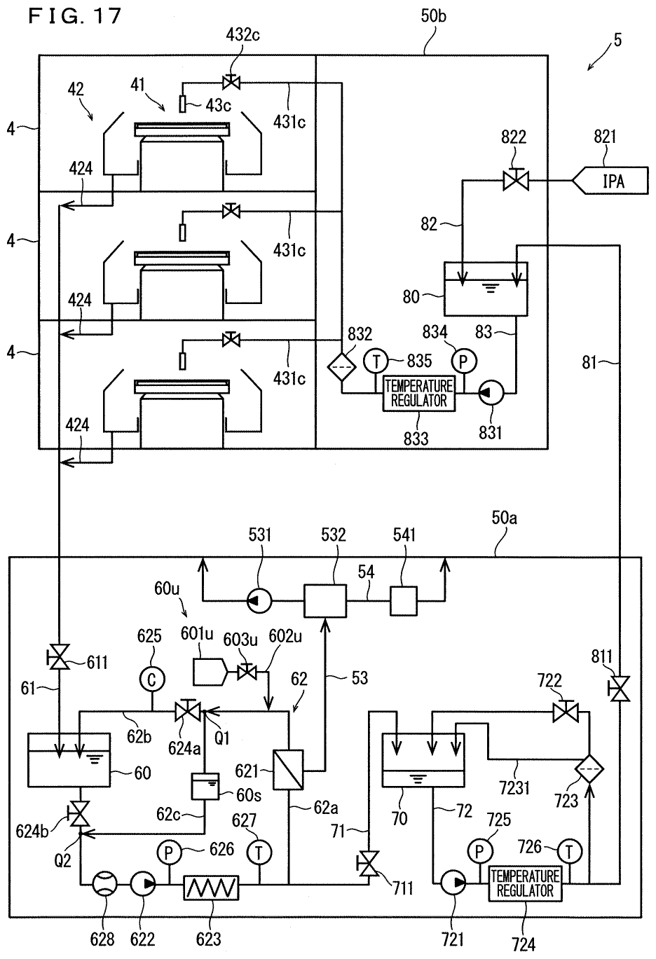

In the organic solvent collector 5 according to the embodiment above, a gas supplier (a gas supply part 60u) may be disposed in the first piping portion 62a or the bypass piping portion 62c (FIG. 17). The gas supply part 60u can include, specifically for example, a gas supply source 601u that supplies a predetermined gas (e.g., nitrogen gas, inert gas, and air), a pipe 602u that connects the gas supply source 601u to the first piping portion 62a or the bypass piping portion 62c (the first piping portion 62a in the example of the drawing), and a valve 603u disposed in the pipe 602u. As described above, the dewaterer 621 separates water contained in the mixed fluid in the second circulating state X2 where the mixed fluid circulates through the first piping portion 62a and the bypass piping portion 62c. During this time, the gas supply part 60u supplies gas to the first piping portion 62a and the bypass piping portion 62c to make up a decrease in the pressure in the pipe due to the separation of water. This maintains the pressure in the first piping portion 62a and the bypass piping portion 62c. When the organic solvent collector 5 includes the gas supply part 60u, it may omit the buffer tank 60s.

### [5-3. Third Modification]

In the organic solvent collector 5 according to the embodiment above, the dewaterer 621 may be disposed in an attitude and an orientation such that the cells 512 extend in the vertical direction and the inlet 521 is disposed at a vertical bottom (i.e., the first outlet 522 is disposed at a vertical top). Here, the mixed fluid flowing through the dewatering circulation pipe 62 flows into the cells 512 from an opening at a vertical bottom of the cells 512.

In this modification, the mixed fluid flowing from the dewatering circulation pipe 62 into the cells 512 which extend in the vertical direction (the cell internal space V1) flows from the bottom to the top inside the cells 512. Thus, the mixed fluid flowing into the cell internal space V1 (particularly, IPA in the liquid state and water in the liquid state which are contained in the mixed fluid) sufficiently remains in the cell internal space V1 under gravity, and fully comes in contact with the separation membrane 51. This increases the probability of separating water contained in the mixed fluid. In other words, the separation efficiency is further enhanced.

### [5-4. Fourth Modification]

When the first piping portion 62a, the bypass piping portion 62c, and the devices disposed in these piping portions can have necessary pressure resistance in the organic solvent collector 5 according to the embodiment above, even if IPA contained in the mixed fluid is brought to a boil, sufficient safety can be ensured. In such a case, the heating temperature T2 may be higher than or equal to the pressurized boiling point T3. For example, the heating temperature T2 may be the boiling point of water or higher at the separation pressure P2. When the heating temperature T2 is the boiling point of water or higher at the separation pressure P2, the mixed fluid flowing into the dewaterer 621 is in the vapor state (i.e., water and IPA contained in the mixed fluid are both in the vapor state). Compared to water in the liquid state, water in the vapor state (steam) has a greater distance between molecules, a smaller force acting between the molecules, and a higher average kinetic energy of the molecules. Therefore, water in the vapor state passes through the separation membrane 51 more easily than water in the liquid state. Thus, the separation efficiency (dewatering efficiency) is enhanced by the vapor state of the water contained in the mixed fluid flowing into the dewaterer 621. A method of supplying the separation membrane 51 with a fluid to be separated in the vapor state is referred to as, for example, a vapor permeation (VP) method.

Even when the heating temperature T2 is a temperature lower than the boiling point of water at the separation pressure P2, a part of the water contained in the mixed fluid heated to the heating temperature T2 has turned into steam. The existence of this steam enhances the separation efficiency.

### [5-5. Other Modifications]

Although the dewaterer 621 is disposed in the first piping portion 62a in the organic solvent collector 5 according to the embodiment above, the dewaterer 621 may be disposed in the bypass piping portion 62c. Furthermore, although the collection tank 60 is disposed in the second piping portion 62b, the collection tank 60 may be disposed in, for example, the first piping portion 62a. Here, the collection tank 60 has pressure resistance that can withstand the separation pressure P2 and has heat resistance that can withstand the heating temperature T2. For example, the collection tank 60 is a pressure vessel (a pressure tank).

According to the embodiment above, the first position Q1 and the second position Q2 can be defined at any point partway in the dewatering circulation pipe 62.

The pressurized and heated mixed fluid does not flow through the separation pipe 53 and the waste pipe 54 in the organic solvent collector 5 according to the embodiment above. Thus, the separation pipe 53, the waste pipe 54, and the devices disposed in these (e.g., the vacuum pump 531, the condenser 532, and the decomposer 541) need not have pressure resistance that can withstand the separation pressure P2 and have heat resistance that can withstand the heating temperature T2. In other words, the separation pipe 53, the waste pipe 54, and the devices disposed in these may be lower in pressure resistance and heat resistance than, for example, the first piping portion 62a. For example, the separation pipe 53 and the waste pipe 54 are resin pipes.

In the organic solvent collector 5 according to the embodiment above, a cooler may be disposed in the first piping portion 62a or the bypass piping portion 62c. Alternatively, a temperature regulator having not only a function as the heater 623 but also a function as a cooler (i.e., a temperature regulator with a cooling capacity and a heating capacity) may be disposed in the first piping portion 62a or the bypass piping portion 62c. In these cases, for example, after the concentrated fluid is obtained in the first piping portion 62a and the bypass piping portion 62c and heating the concentrated fluid is stopped (Step S208), the concentrated fluid can be cooled using the cooler or the temperature regulator. This allows the temperature of the concentrated fluid to be lowered promptly to a temperature lower than the normal boiling point T1.

In the organic solvent collector 5 according to the embodiment above, the structure of the dewaterer 621 can be appropriately modified. For example, the separation membrane 51 included in the dewaterer 621 is not limited to a zeolite membrane. The separation membrane 51 may be, for example, an organic separation membrane. The organic separation membrane is, for example, an organic membrane made of polyvinyl alcohol, chitosan, or polyimide. Alternatively, the separation membrane 51 may be a carbon nanotube (CNT) separation membrane. The CNT separation membrane is, for example, a membrane obtained by adding carbon nanotube to a membrane made of, for example, polyamide. Alternatively, the separation membrane 51 may be made of a two-dimensional material. The two-dimensional material is a material consisting of an atomic monolayer, specifically, for example, molybdenum sulfide (MoS₂), and a composite atomic layer compound containing an early transition metal (titanium, vanadium, etc.) and a light element (carbon or nitrogen). Alternatively, the separation membrane 51 may be made of a metal-organic framework (MOF) material, or a carbon material (e.g., graphene, graphene oxide, etc.).

In the substrate processing apparatus 100 according to the embodiment above, the processing units 4 from and to which the organic solvent collector 5 collects and supplies an organic solvent need not be the processing units 4 included in the same tower. In other words, the organic solvent collector 5 may collect and supply an organic solvent from and to at least one of the processing units 4 arbitrarily chosen. Furthermore, the processing unit 4 from which the organic solvent collector 5 collects an organic solvent may be different from the processing unit 4 to which the organic solvent collector 5 supplies an organic solvent.

In the substrate processing apparatus 100 according to the embodiment above, an organic solvent is not limited to IPA. The organic solvent may be, for example, at least one of hydrofluoroethers (HFE), methanol, ethanol, acetone, or trans-1,2-dichloroethylene. The organic solvent need not consist of a single component, but may be a liquid obtained by mixing a plurality of components.

In the substrate processing apparatus 100 according to the embodiment above, a rinse liquid may be of a variety of types which contain water. The rinse liquid may be, for example, one of carbonated water, electrolytic ionized water, hydrogen water, ozonized water, or a diluted hydrochloric acid (for example, a hydrochloric acid having a dilution concentration of 10 to 100 ppm).

The substrate W to be processed by the substrate processing apparatus 100 according to the embodiment above need not always be a semiconductor substrate. Examples of the substrate W to be processed may include a photolithographic mask glass substrate, a liquid crystal display glass substrate, a plasma display glass substrate, a field-emission display (FED) substrate, an optical disk substrate, a magnetic disk substrate, and a magneto-optical disk substrate. The substrate W to be processed need not be completely circular but may have a shaped portion such as a notch and an orientation flat.

Although the substrate processing apparatus and the substrate processing method are described above in detail, the description is in all aspects illustrative and does not restrict the substrate processing apparatus and the substrate processing method. Therefore, numerous modifications and variations that have not yet been exemplified are devised without departing from the scope of the present disclosure. The structures described in the embodiment and the modifications can be appropriately combined or omitted unless any contradiction occurs.

The present disclosure includes the following aspects.

The first aspect is a substrate processing apparatus, and includes: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a circulation pipe connected to the collection tank; a dewaterer disposed in the circulation pipe and including a separation membrane that allows the water to pass through and does not allow the organic solvent to pass through; a pump disposed in the circulation pipe; and a heater disposed in the circulation pipe, wherein a first position and a second position are defined in the circulation pipe, and the circulation pipe includes: a first pipe (a first piping portion) connecting a downstream side of the second position and an upstream side of the first position; a second pipe (a second piping portion) connecting a downstream side of the first position and an upstream side of the second position; and a bypass pipe (a bypass piping portion) connecting the downstream side of the first position and the upstream side of the second position through a path different from a path of the second pipe, the dewaterer is disposed in the first pipe or the bypass pipe, and the pump pressurizes the mixed fluid at a separation pressure higher than a circulation pressure necessary for circulation and the heater heats the mixed fluid to a predetermined heating temperature, in a state where the mixed fluid circulates through the first pipe and the bypass pipe.

The second aspect is the substrate processing apparatus according to the first aspect, and the collection tank is disposed in the second pipe.

The third aspect is the substrate processing apparatus according to the first or second aspect, and the heating temperature is higher than a boiling point of the organic solvent at atmospheric pressure, and is lower than a boiling point of the organic solvent at the separation pressure.

The fourth aspect is the substrate processing apparatus according to the third aspect, and, in a state where the mixed fluid circulates through the first pipe and the bypass pipe, after the pump pressurizes the mixed fluid at the separation pressure, the heater heats the mixed fluid to the heating temperature.

The fifth aspect is the substrate processing apparatus according to the third or fourth aspect, and, in a state where a concentrated fluid being obtained by separating the water from the mixed fluid circulates through the first pipe and the bypass pipe, the heater stops heating the concentrated fluid, and after a temperature of the concentrated fluid becomes lower than the boiling point of the organic solvent at atmospheric pressure, the pump stops pressurizing the concentrated fluid.

The sixth aspect is the substrate processing apparatus according to any one of the first to fifth aspects, and includes: a vacuum pump that reduces a pressure of a space in the dewaterer into which the water that has passed through the separation membrane flows.

The seventh aspect is the substrate processing apparatus according to any one of the first to sixth aspects, and includes: a purification tank connected to the collection tank through the circulation pipe and a feed pipe and storing a concentrated fluid obtained by separating the water from the mixed fluid; and a filter disposed in a pipe connected to the purification tank and capturing a removal target substance contained in the concentrated fluid flowing through the pipe.

The eighth aspect is the substrate processing apparatus according to the seventh aspect, and the concentrated fluid stored in the purification tank is fed to the organic solvent supply nozzle through the filter, and is supplied to the substrate.

The ninth aspect is the substrate processing apparatus according to any one of the first to eighth aspects, and the circulation pipe further includes a plurality of branch pipes (branched portions) disposed between a branching position that is defined downstream of the first position and a merging position that is defined upstream of the second position, and the collection tank is disposed in each of the plurality of branch pipes (branched portions).

The tenth aspect is the substrate processing apparatus according to any one of the first to ninth aspects, and the dewaterer is disposed in an attitude such that a cell that forms a flow path of the mixed fluid in the separation membrane extends in a vertical direction, and the mixed fluid flowing through the circulation pipe flows into the cell from an opening at a vertical bottom of the cell.

The eleventh aspect is the substrate processing apparatus according to any one of the first, second, and sixth to tenth aspects, and the heating temperature is a boiling point of the water or higher at the separation pressure.

The twelfth aspect is a substrate processing method and includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; filling a circulation pipe connected to the collection tank with the mixed fluid stored in the collection tank; circulating the mixed fluid through a first pipe and a bypass pipe, among the first pipe, a second pipe, and the bypass pipe included in the circulation pipe; pressurizing the mixed fluid circulating through the first pipe and the bypass pipe, at a separation pressure higher than a circulation pressure necessary for circulation; heating the mixed fluid circulating through the first pipe and the bypass pipe, to a predetermined heating temperature; and causing the mixed fluid to flow into a dewaterer including a separation membrane that allows the water to pass through and does not allow the organic solvent to pass through, and separating the water from the mixed fluid, the mixed fluid circulating through the first pipe and the bypass pipe, wherein a first position and a second position are defined in the circulation pipe, the first pipe is a pipe (a piping portion) connecting a downstream side of the second position and an upstream side of the first position, the second pipe is a pipe (a piping portion) connecting a downstream side of the first position and an upstream side of the second position, and the bypass pipe is a pipe (a piping portion) connecting the downstream side of the first position and the upstream side of the second position through a path different from a path of the second pipe.

Since each of the first and twelfth aspects allows the pressurized and heated mixed fluid to flow into the dewaterer, water can be efficiently separated from the mixed fluid.

Since the collection tank is disposed in the second pipe, the pressurized and heated mixed fluid does not flow into the collection tank according to the second aspect. Thus, the collection tank need not have pressure resistance that can withstand the separation pressure.

The third aspect can sufficiently increase the temperature of the mixed fluid without bringing the organic solvent to a boil. This can achieve the high separation efficiency while ensuring safety.

Since heating is performed after the boiling point is increased by pressurizing the mixed fluid according to the fourth aspect, the organic solvent is not brought to a boil during the heating.

Since the pressurized state is maintained until the temperature of the concentrated fluid is lowered to a temperature lower than the boiling point of the organic solvent at atmospheric pressure according to the fifth aspect, the organic solvent is not brought to a boil during lowering of the temperature.

Reducing a pressure of a space in the dewaterer into which the water that has passed through the separation membrane flows according to the sixth aspect can promote the separation of water.

The seventh aspect can increase the cleanliness of the concentrated fluid obtained by separating water from the mixed fluid, by removing a removal target substance from the concentrated fluid.

According to the eighth aspect, after the cleanliness of the concentrated fluid obtained by separating water from the mixed fluid that contains the water supplied to the substrate and then collected and the organic solvent supplied to the substrate and then collected is increased, the concentrated fluid is again supplied to the substrate. Thus, the amounts of the organic solvent to be used and to be discharged can be reduced.

According to the ninth aspect, since the plurality of collection tanks are disposed in the circulation pipe, the collection tank to be feed destinations can be switched, thereby enabling the water supplied to the substrate and then collected and the organic solvent supplied to the substrate and then collected to be fed without interruption.

According to the tenth aspect, the mixed fluid flowing from the circulation pipe into the cell extending in the vertical direction flows from the bottom to the top inside the cell. Thus, the mixed fluid flowing inside the cell sufficiently remains inside the cell, and fully comes in contact with the separation membrane. This further enhances the separation efficiency.

The eleventh aspect allows the water contained in the mixed fluid to flow into the dewaterer in the vapor state. This can enhance the separation efficiency using the separation membrane.

While the disclosure has been shown and described in detail, the foregoing description is in all aspects illustrative and not restrictive. It is therefore understood that numerous modifications and variations can be devised.

What is claimed is:

1. A substrate processing apparatus, comprising:
a rinse liquid supply nozzle that supplies a substrate with a rinse liquid containing water;
an organic solvent supply nozzle that supplies an organic solvent to the substrate;
a collection tank that stores a mixed fluid containing the water supplied to the substrate and then collected and the organic solvent supplied to the substrate and then collected;
a circulation pipe connected to the collection tank;
a dewaterer disposed in the circulation pipe and including a separation membrane that allows the water to pass through and does not allow the organic solvent to pass through;
a pump disposed in the circulation pipe; and
a heater disposed in the circulation pipe,
wherein a first position and a second position are defined in the circulation pipe, and the circulation pipe includes:
a first pipe connecting a downstream side of the second position and an upstream side of the first position;
a second pipe connecting a downstream side of the first position and an upstream side of the second position; and
a bypass pipe connecting the downstream side of the first position and the upstream side of the second position through a path different from a path of the second pipe,
the dewaterer is disposed in the first pipe or the bypass pipe, and
the pump pressurizes the mixed fluid at a separation pressure higher than a circulation pressure necessary for circulation and the heater heats the mixed fluid to a predetermined heating temperature, in a state where the mixed fluid circulates through the first pipe and the bypass pipe.

2. The substrate processing apparatus according to claim 1,
wherein the collection tank is disposed in the second pipe.

3. The substrate processing apparatus according to claim 1,
wherein the heating temperature is higher than a boiling point of the organic solvent at atmospheric pressure, and is lower than a boiling point of the organic solvent at the separation pressure.

4. The substrate processing apparatus according to claim 3,
wherein, in a state where the mixed fluid circulates through the first pipe and the bypass pipe, after the pump pressurizes the mixed fluid at the separation pressure, the heater heats the mixed fluid to the heating temperature.

5. The substrate processing apparatus according to claim 3,
wherein, in a state where a concentrated fluid being obtained by separating the water from the mixed fluid circulates through the first pipe and the bypass pipe, the heater stops heating the concentrated fluid, and after a temperature of the concentrated fluid becomes lower than the boiling point of the organic solvent at atmospheric pressure, the pump stops pressurizing the concentrated fluid.

6. The substrate processing apparatus according to claim 1, further comprising
a vacuum pump that reduces a pressure of a space in the dewaterer into which the water that has passed through the separation membrane flows.

7. The substrate processing apparatus according to claim 1, further comprising:
a purification tank connected to the collection tank through the circulation pipe and a feed pipe and storing a concentrated fluid obtained by separating the water from the mixed fluid; and
a filter disposed in a pipe connected to the purification tank and capturing a removal target substance contained in the concentrated fluid flowing through the pipe.

8. The substrate processing apparatus according to claim 7,
wherein the concentrated fluid stored in the purification tank is fed to the organic solvent supply nozzle through the filter, and is supplied to the substrate.

9. The substrate processing apparatus according to claim 1,
wherein the circulation pipe further includes a plurality of branch pipes disposed between a branching position that is defined downstream of the first position and a merging position that is defined upstream of the second position, and
the collection tank is disposed in each of the plurality of branch pipes.

10. The substrate processing apparatus according to claim 1,
wherein the dewaterer is disposed in an attitude such that a cell that forms a flow path of the mixed fluid in the separation membrane extends in a vertical direction, and
the mixed fluid flowing through the circulation pipe flows into the cell from an opening at a vertical bottom of the cell.

11. The substrate processing apparatus according to claim 1,
wherein the heating temperature is a boiling point of the water or higher at the separation pressure.

12. A substrate processing method, comprising:
supplying a substrate with a rinse liquid containing water;
supplying an organic solvent to the substrate;
storing, in a collection tank, a mixed fluid containing the water supplied to the substrate and then collected and the organic solvent supplied to the substrate and then collected;
filling a circulation pipe connected to the collection tank with the mixed fluid stored in the collection tank;
circulating the mixed fluid through a first pipe and a bypass pipe, among the first pipe, a second pipe, and the bypass pipe included in the circulation pipe;
pressurizing the mixed fluid circulating through the first pipe and the bypass pipe, at a separation pressure higher than a circulation pressure necessary for circulation;
heating the mixed fluid circulating through the first pipe and the bypass pipe, to a predetermined heating temperature; and
causing the mixed fluid to flow into a dewaterer including a separation membrane that allows the water to pass through and does not allow the organic solvent to pass through, and separating the water from the mixed fluid, the mixed fluid circulating through the first pipe and the bypass pipe,
wherein a first position and a second position are defined in the circulation pipe, the first pipe is a pipe connecting a downstream side of the second position and an upstream side of the first position, the second pipe is a pipe connecting a downstream side of the first position and an upstream side of the second position, and the bypass pipe is a pipe connecting the downstream side of the first position and the upstream side of the second position through a path different from a path of the second pipe.
